(19) United States
(12) Patent Application Publication
(10) Pub. No.: US 2024/0255798 A1
(43) Pub. Date: Aug. 1, 2024

(54) DECORATIVE FILM, DECORATIVE PANEL, AND DISPLAY DEVICE

(71) Applicant: FUJIFILM Corporation, Tokyo (JP)

(72) Inventors: Yuichi HAYATA, Kanagawa (JP); Yuki NAKAGAWA, Kanagawa (JP); Makoto ISHIGURO, Kanagawa (JP)

(73) Assignee: FUJIFILM Corporation, Tokyo (JP)

(21) Appl. No.: 18/434,883

(22) Filed: Feb. 7, 2024

Related U.S. Application Data
(63) Continuation of application No. PCT/JP2022/030786, filed on Aug. 12, 2022.

(30) Foreign Application Priority Data
Aug. 13, 2021 (JP) 2021-131978
Jul. 14, 2022 (JP) 2022-113386

(51) Int. Cl. G02F 1/1335; G02F 1/13363; G02F 1/137; H10K 59/80

(52) U.S. Cl. CPC G02F 1/133553; G02F 1/133541; G02F 1/133638; G02F 1/13718; H10K 59/878; H10K 59/8793

(57) ABSTRACT

The present disclosure provides a decorative film including a reflective layer including a region having a reflectivity of at least 5% or more and a layer having a convex structure with a height of at least 1 μm or more on an outermost surface, a decorative panel, and a display device.

### CROSS-REFERENCE TO RELATED APPLICATIONS

This application is a continuation application of International Application No. PCT/JP2022/030786, filed Aug. 12, 2022, which is incorporated herein by reference. Further, this application claims priority from Japanese Patent Application No. 2021-131978, filed Aug. 13, 2021, and Japanese Patent Application No. 2022-113386, filed Jul. 14, 2022, which are incorporated herein by reference.

### BACKGROUND OF THE INVENTION

### 1. Field of the Invention

The present disclosure relates to a decorative film, a decorative panel, and a display device.

### 2. Description of the Related Art

A decorative molded article, in which a decorative film is disposed on a surface of a resin molded article to color the surface in a desired color tone or to provide a desired pattern on the surface, has been known.

The decorative molded article is obtained, for example, by previously disposing a decorative molded film in a mold and injection-molding a base material resin into the mold, thereby having a structure in which the surface of the resin molded article is integrated with the decorative film. The decorative molded film refers to a film formed by attaching a decorative film to a base material for molding. Here, the injection mold of the base material resin after previously disposing the decorative molded film in the mold is generally referred to as film insert molding or simply insert molding. In addition, the decorative molded article may be manufactured by attaching a decorative film to a molded article after molding.

In addition, as a hot stamp foil in the related art, JP2001-105795A discloses a hot stamp foil characterized in that a cholesteric liquid crystalline polymer layer having a selective reflection wavelength range in visible light is laminated as a transfer layer. In addition, JP2017-97114A discloses that retroreflective property is improved by subjecting a cholesteric liquid crystal layer to an uneven processing.

### SUMMARY OF THE INVENTION

An object to be achieved by an aspect of the present invention is to provide a decorative film having excellent visibility. An object to be achieved by another embodiment of the present disclosure is to provide a decorative panel using the decorative film, and a display device.

The methods for achieving the above-described objects include the following aspects.
<1> A decorative film comprising:
a reflective layer including a region having a reflectivity of at least 5% or more; and
a layer having a convex structure with a height of at least 1 μm or more on an outermost surface.
<2> The decorative film according to <1>,
in which a total light transmittance in a wavelength range of 380 nm or more and 800 nm or less is 50% or more.
<3> The decorative film according to <1> or <2>,
in which at least a part of the convex structure has a height of 5 μm or more.
<4> The decorative film according to any one of <1> to <3>,
in which at least a part of the convex structure has light absorbability.
<5> The decorative film according to any one of <1> to <4>,
in which the reflective layer is a layer including a cholesteric liquid crystal.
<6> The decorative film according to any one of <1> to <5>, further comprising:
a λ/4 phase difference plate or a circularly polarizing plate at a position opposite to a surface having an uneven structure with a depth of at least 1 μm or more with respect to the reflective layer.
<7> The decorative film according to any one of <1> to <6>, further comprising:
a resin base material on a side of the reflective layer opposite to a side on which the layer having a convex structure is provided.
<8> The decorative film according to any one of <1> to <7>,
in which the layer having a convex structure contains coloring particles.
<9> The decorative film according to any one of <1> to <8>,
in which the layer having a convex structure contains black particles.
<10> A decorative panel on which the decorative film according to any one of <1> to
<9> is mounted.
<11> A display device on which the decorative panel according to <10> is mounted.
<12> The display device according to <11>,
in which emitted light of the display device is linearly polarized light.
<13> The display device according to <11>,
in which the display device is a liquid crystal display device or an organic electroluminescent display device.

According to one embodiment of the present disclosure, a decorative film having excellent visibility is provided. According to another embodiment of the present disclosure, a decorative panel using the decorative film is provided. According to still another embodiment of the present disclosure, a display device using the decorative panel is provided.

### BRIEF DESCRIPTION OF THE DRAWINGS

FIG. 1 is a schematic cross-sectional view showing an example of a decorative film according to an embodiment of the present disclosure.

FIG. 2 is a schematic cross-sectional view showing an example of an exposure mask pattern.

FIG. 3 is a schematic cross-sectional view showing an example of a decorative panel according to an embodiment of the present disclosure.

FIG. 4 is a schematic cross-sectional view showing another example of the exposure mask pattern.

FIG. 5 is a schematic cross-sectional view showing still another example of the exposure mask pattern.

### DESCRIPTION OF THE PREFERRED EMBODIMENTS

Hereinafter, embodiments of the present disclosure will be described. However, the present disclosure is not limited to the following embodiments, and can be implemented with appropriate modification within the scope of the object of the present disclosure. In a case where the embodiments of the present disclosure are described with reference to the drawings, the description of overlapping constituent elements and reference numerals may be omitted. The constituent elements indicated by the same reference numeral in the drawings mean the same constituent element. A dimensional ratio in the drawings does not necessarily represent the actual dimensional ratio.

In a case where substitution or unsubstitution is not noted in regard to the notation of a “group” (atomic group) in the present disclosure, the “group” includes not only a group not having a substituent but also a group having a substituent. For example, an “alkyl group” includes not only an alkyl group having no substituent (unsubstituted alkyl group), but also an alkyl group having a substituent (substituted alkyl group).

In the present disclosure, “light” means an actinic ray or radiation.

In the present disclosure, “actinic ray” or “radiation” means, for example, a bright line spectrum of a mercury lamp, far ultraviolet ray typified by an excimer laser, extreme ultraviolet ray (EUV light), X-ray, electron beam (EB), and the like.

In the present disclosure, unless otherwise specified, “exposure” includes not only exposure by a bright line spectrum of a mercury lamp, far ultraviolet ray typified by an excimer laser, extreme ultraviolet ray (EUV light), X-ray, and the like, but also exposure by a particle beam such as an electron beam and an ion beam.

In the present disclosure, “to” is used to refer to a meaning including numerical values denoted before and after “to” as a lower limit value and an upper limit value.

In the present disclosure, (meth)acrylate represents acrylate and methacrylate, and (meth)acrylic represents acrylic and methacrylic.

In the present disclosure, a weight-average molecular weight (Mw), a number-average molecular weight (Mn), and a dispersity (also referred to as molecular weight distribution) (Mw/Mn) of a resin component are defined as a value in terms of polystyrene according to a gel permeation chromatography (GPC) measurement (solvent: tetrahydrofuran, flow amount (sample injection amount): 10 μL, column: TSK gel Multipore HXL-M manufactured by Tosoh Corporation, column temperature: 40° C., flow rate: 1.0 mL/min, detector: refractive index detector) using a GPC device (HLC-8120GPC manufactured by Tosoh Corporation).

In the present disclosure, in a case where a plurality of substances corresponding to each component in a composition is present, the amount of each component in the composition means the total amount of the plurality of substances present in the composition, unless otherwise specified.

In the present disclosure, a term “step” denotes not only an individual step but also a step which is not clearly distinguishable from another step as long as an effect expected from the step can be achieved.

In the present disclosure, a “total solid content” refers to a total mass of components obtained by removing a solvent from the whole composition of the composition. In addition, a “solid content” is a component obtained by removing a solvent from the whole composition of the composition, and for example, the component may be solid or may be liquid at 25° C.

In the present disclosure, “% by mass” has the same definition as that for “% by weight”, and “part by mass” has the same definition as that for “part by weight”.

In addition, in the present disclosure, a combination of two or more preferred aspects is a more preferred aspect.

### (Decorative Film)

The decorative film according to one embodiment of the present disclosure includes a reflective layer including a region having a reflectivity of at least 5% or more and a layer having a convex structure with a height of at least 1 μm or more on an outermost surface. An application of the decorative film according to one embodiment of the present disclosure is not particularly limited, and specific examples thereof include a decoration of display devices (for example, wearable devices and smartphones), home appliances, audio products, computers, display devices, in-vehicle products, watches, accessories, optical parts, doors, window glasses, and building materials. Among these, the decorative film according to one embodiment of the present disclosure can be suitably used for a decoration of display devices and in-vehicle products, and can be particularly suitably used for a display used in in-vehicle interiors.

In the related art, as a surface decoration used in articles such as home appliances, electronic apparatuses, and mobile phones, for example, printing, painting, vapor deposition, or plating has been used. However, for example, from the aspects of problems such as functionality addition and environmental load, and the possibility of replacement, a decoration technique by using a decorative film has been widely used. For example, WO2018/079606A describes a transparent decorative film including a circularly polarizing plate and a circularly polarized light reflection layer disposed on the circularly polarizing plate. However, in the above-described method, since light from the outside, such as sunlight and indoor light, is also reflected, there is a problem that visibility of the decorative film is insufficient.

As a result of intensive studies by the present inventors, it has been found that, according to the decorative film including the above-described configuration, a decorative film which has high visibility of decoration (in the present disclosure, also referred to as “high visibility of the decorative film”) is useful as a material for a decorative molded article is provided. In the present disclosure, the “high visibility of decoration” means that, for example, even in a case where the object is exposed to light such as sunlight and indoor light, a design of the decoration is clearly visible. The above-described effect is preferable from the viewpoint that a desired design can be visually recognized regardless of, for example, an environment in which a display or the like is installed.

In addition, new designability is required from the widespread preference of users. For example, in recent years, there is a demand for a transmissive decorative film (transparent decorative film) in which a scene on the other side can be seen through the film itself, and a specific display can be visually recognized from one side (surface) and the display cannot be substantially visually recognized from the other side (back surface). In particular, on a back surface, in a case where a specific display substantially displayed on the front surface cannot be visually recognized, and further, in a case where a display or an image of a hue completely different from that of the specific display can be displayed, the decorative effect is further enhanced.

Furthermore, in the decorative film in the related art, there is a problem that smoothness is insufficient in a case of touching the surface.

According to the decorative film including the above-described configuration, the present inventors have found that a decorative film which has high visibility of a light source in a case where the light source is installed on the back surface, and provides a pleasant tactile sensation in a case of touching the surface of the decorative film is provided.

Hereinafter, the decorative film according to the embodiment of the present disclosure will be described in detail.

### <Reflective Layer>

The decorative film according to one embodiment of the present disclosure includes a reflective layer. The reflective layer includes a region having a reflectivity of at least 5% or more in a wavelength range of 380 nm or more and 800 nm or less. Examples of the reflective layer include a layer including a cholesteric liquid crystal (hereinafter, also simply referred to as a “cholesteric liquid crystal layer”), a layer including flat metal particles, an optical multilayer film, and a layer including a chromic material. Among the above-described reflective layers, from the viewpoint of molding processing suitability and impact resistance, a cholesteric liquid crystal layer or an optical multilayer film is preferable, and a cholesteric liquid crystal layer is more preferable.

### <<Liquid Crystal Composition>>

The cholesteric liquid crystal layer is a layer obtained by curing a liquid crystal composition. The liquid crystal composition is a composition containing a liquid crystal compound. From the viewpoint of moldability and temporary support peeling property, as the liquid crystal compound used in the present disclosure, it is preferable to use at least a cholesteric liquid crystal compound having one ethylenically unsaturated group or one cyclic ether group. For example, the liquid crystal composition for forming the cholesteric liquid crystal layer contains, with respect to a total solid content of the liquid crystal composition, 25% by mass or more of the cholesteric liquid crystal compound having one ethylenically unsaturated group or one cyclic ether group, and furthermore, may contain other components (for example, a chiral agent, an alignment control agent, a polymerization initiator, and an alignment assistant).

—Cholesteric liquid crystal compound having one ethylenically unsaturated group or one cyclic ether group—

It is preferable that the liquid crystal composition contains, as the liquid crystal compound, 25% by mass or more of a cholesteric liquid crystal compound (hereinafter, also referred to as a “specific liquid crystal compound”) having one ethylenically unsaturated group or one cyclic ether group.

The ethylenically unsaturated group in the specific liquid crystal compound is not particularly limited, and examples thereof include a (meth)acryloxy group, a (meth)acrylamide group, a vinyl group, a vinyl ester group, and a vinyl ether group. As the ethylenically unsaturated group, from the viewpoint of reactivity, a (meth)acryloxy group, a (meth)acrylamide group, or an aromatic vinyl group is preferable, a (meth)acryloxy group or a (meth)acrylamide group is more preferable, and a (meth)acryloxy group is particularly preferable.

The cyclic ether group in the specific liquid crystal compound is not particularly limited, but from the viewpoint of reactivity, an epoxy group or an oxetanyl group is preferable, and an oxetanyl group is particularly preferable.

From the viewpoint of reactivity, and suppressing change in reflectance and change in tint after molding, the specific liquid crystal compound is preferably a cholesteric liquid crystal compound having one ethylenically unsaturated group. The liquid crystal composition more preferably contains 25% by mass or more of the cholesteric liquid crystal compound having one ethylenically unsaturated group with respect to the total solid content of the liquid crystal composition.

The specific liquid crystal compound may have both ethylenically unsaturated group and cyclic ether group in one molecule, but it is assumed that the number of ethylenically unsaturated groups is 1 or the number of cyclic ether groups is 1. In addition, in a case where the number of ethylenically unsaturated groups in the specific liquid crystal compound is 1, for example, the specific liquid crystal compound may be a compound having one ethylenically unsaturated group and one or more cyclic ether groups.

In a case where the liquid crystal composition includes a cholesteric liquid crystal compound having one ethylenically unsaturated group, from the viewpoint of suppressing change in reflectance and change in tint after molding, the above-described liquid crystal composition preferably includes a radical polymerization initiator, and more preferably includes a photoradical polymerization initiator.

In a case where the liquid crystal composition includes a cholesteric liquid crystal compound having one cyclic ether group, from the viewpoint of suppressing change in reflectance and change in tint after molding, the above-described liquid crystal composition preferably includes a cationic polymerization initiator, and more preferably includes a photocationic polymerization initiator.

From the viewpoint of suppressing change in reflectance and change in tint after molding, the specific liquid crystal compound is preferably a cholesteric liquid crystal compound having both ethylenically unsaturated group and cyclic ether group, and more preferably a cholesteric liquid crystal compound having one ethylenically unsaturated group and one cyclic ether group.

It is sufficient that the specific liquid crystal compound is a compound having a liquid crystal structure, and the specific liquid crystal compound may be a rod-like liquid crystal compound or a disk-like liquid crystal compound. From the viewpoint of ease of adjusting a pitch of a helical structure in the cholesteric liquid crystal layer, and viewpoint of suppressing change in reflectance and change in tint after molding, the specific liquid crystal compound is preferably a rod-like liquid crystal compound.

As the rod-like liquid crystal compound, azomethines, azoxys, cyano biphenyls, cyanophenyl esters, benzoic acid esters, cyclohexane carboxylic acid phenyl esters, cyanophenyl cyclohexanes, cyano-substituted phenyl pyrimidines, alkoxy-substituted phenyl pyrimidines, phenyl dioxanes, tolanes, or alkenylcyclohexylbenzonitriles are preferably used. In addition to the above-described low-molecular weight liquid crystal compounds, a liquid crystalline polymer compound can also be used. As the rod-like liquid crystal compound, a compound having one ethylenically unsaturated group or one cyclic ether group, among compounds described in “Makromol. Chem., vol. 190, p. 2255 (1989), Advanced Materials, vol. 5, p. 107 (1993)”, U.S. Pat. Nos. 4,683,327A, 5,622,648A, 5,770,107A, WO1995/022586A, WO1995/024455A, WO1997/000600A, WO1998/023580A, WO1998/052905A, JP1989-272551A (JP-H1-272551A), JP1994-16616A (JP-H6-16616A), JP1995-110469A (JP-H7-110469A), JP1999-80081A (JP-H11-80081A), and JP2001-328973A, can be used. Furthermore, as the rod-like liquid crystal compound, for example, a compound having one ethylenically unsaturated group or one cyclic ether group, among compounds described in JP1999-513019A (JP-H11-513019A) and JP2007-279688A, can also be preferably used. The cholesteric liquid crystal layer is more preferably a layer in which the alignment is fixed by polymerizing the rod-like liquid crystal compound.

As the disk-like liquid crystal compound, for example, a compound having one ethylenically unsaturated group or one cyclic ether group, among compounds described in JP2007-108732A or JP2010-244038A, can be preferably used.

Preferred specific examples of the specific liquid crystal compound include compounds shown below, but it is needless to say that the specific liquid crystal compound is not limited thereto.

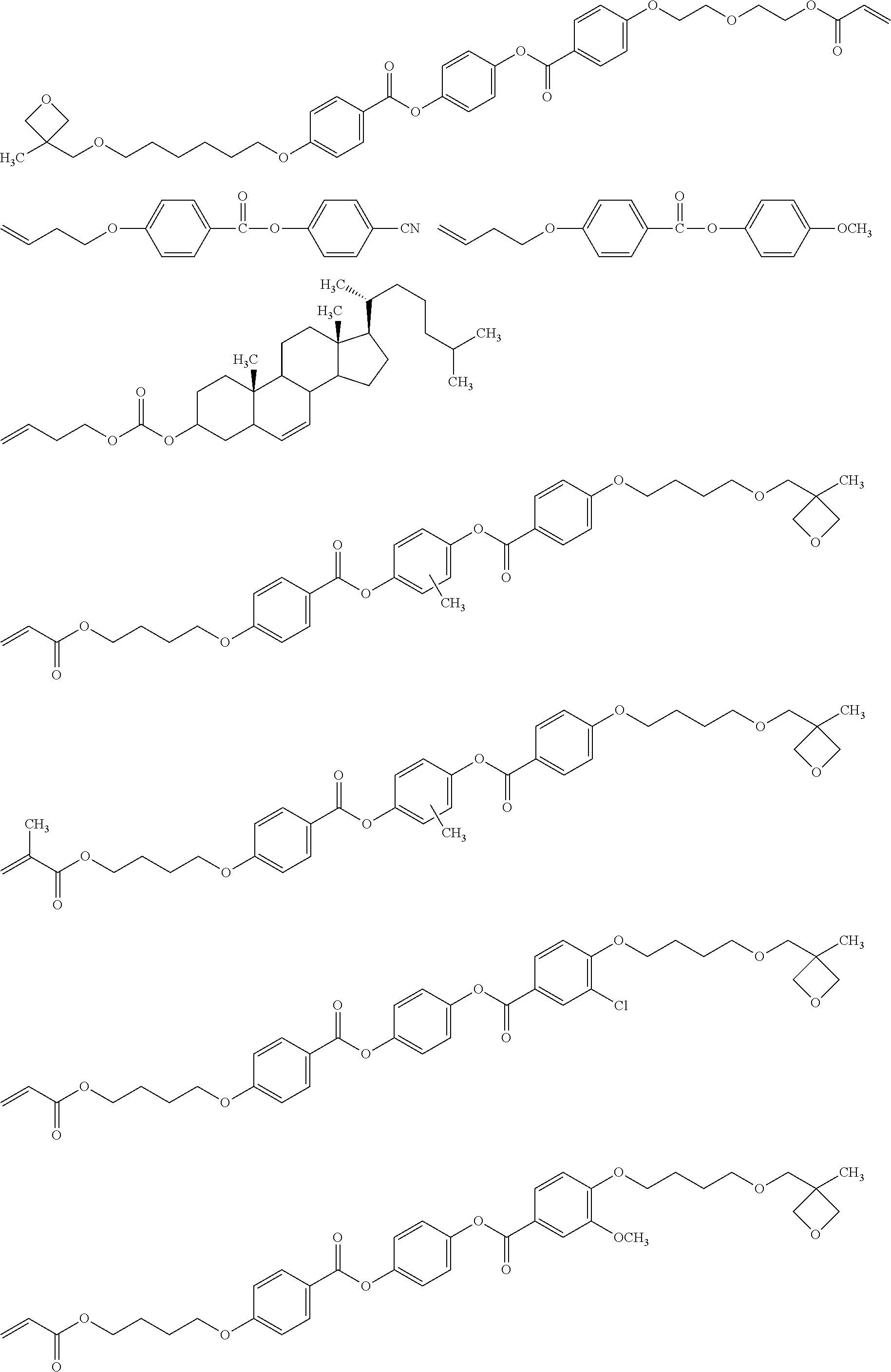

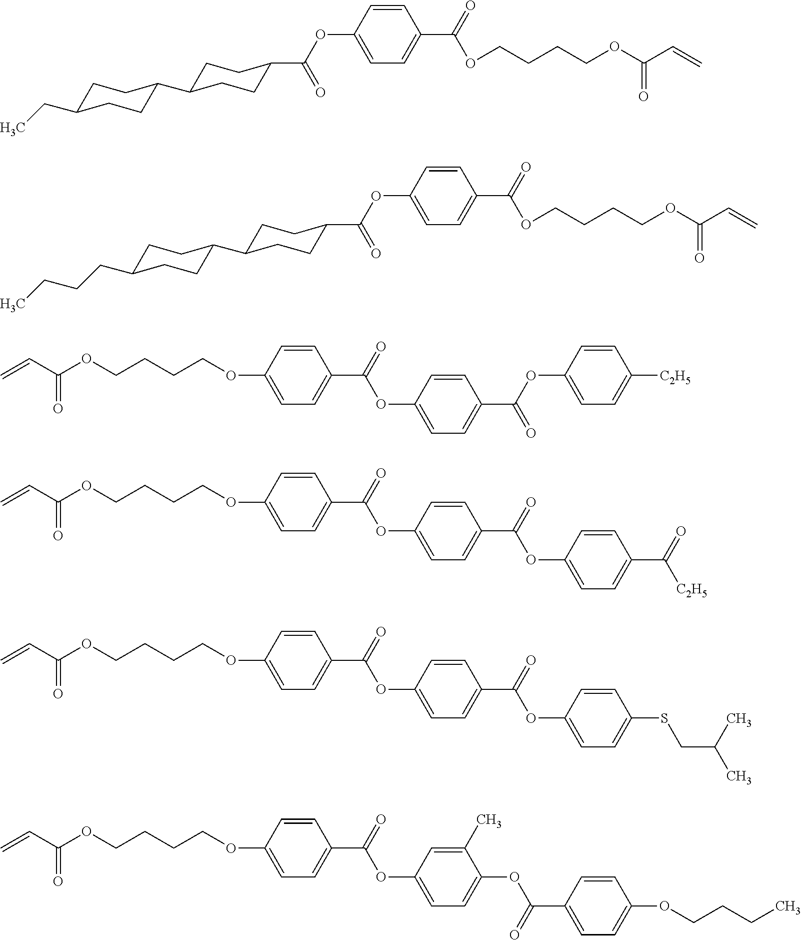

The liquid crystal composition may include one specific liquid crystal compound alone, or may include two or more specific liquid crystal compounds. A content of the specific liquid crystal compound is preferably 25% by mass or more with respect to the total solid content of the liquid crystal composition. In a case where the content of the specific liquid crystal compound is 25% by mass or more, a decorative film which has a small change in reflectance after molding is obtained. In addition, from the viewpoint of suppressing change in reflectance and change in tint after molding, with respect to the total solid content of the liquid crystal composition, the content of the specific liquid crystal compound is preferably 30% by mass or more, more preferably 40% by mass or more, still more preferably 60% by mass to 99% by mass, and particularly preferably 80% by mass to 98% by mass.

### —Other Cholesteric Liquid Crystal Compound—

The liquid crystal composition may include other cholesteric liquid crystal compounds (hereinafter, also simply referred to as “other liquid crystal compounds”) other than the specific liquid crystal compound. Examples of other liquid crystal compounds include cholesteric liquid crystal compounds having no ethylenically unsaturated group and cyclic ether group, cholesteric liquid crystal compounds having two or more ethylenically unsaturated groups and no cyclic ether group, cholesteric liquid crystal compounds having two or more cyclic ether groups and no ethylenically unsaturated group, and cholesteric liquid crystal compounds having two or more ethylenically unsaturated groups and two or more cyclic ether groups. Among these, from the viewpoint of suppressing change in reflectance and change in tint after molding, the other liquid crystal compounds are preferably at least one compound selected from the group consisting of cholesteric liquid crystal compounds having no ethylenically unsaturated group and no cyclic ether group, cholesteric liquid crystal compounds having two or more ethylenically unsaturated groups and no cyclic ether group, and cholesteric liquid crystal compounds having two or more cyclic ether groups and no ethylenically unsaturated group, more preferably at least one compound selected from the group consisting of cholesteric liquid crystal compounds having no ethylenically unsaturated group and no cyclic ether group, cholesteric liquid crystal compounds having two ethylenically unsaturated groups and no cyclic ether group, and cholesteric liquid crystal compounds having two or more cyclic ether groups and no ethylenically unsaturated group, and particularly preferably at least one compound selected from the group consisting of cholesteric liquid crystal compounds having no ethylenically unsaturated group and no cyclic ether group or cholesteric liquid crystal compounds having two ethylenically unsaturated groups and no cyclic ether group.

As the other liquid crystal compounds, a known cholesteric liquid crystal compound can be used. As a rod-like liquid crystal compound in the other liquid crystal compounds, for example, compounds described in “Makromol. Chem., vol. 190, p. 2255 (1989), Advanced Materials, vol. 5, p. 107 (1993)”, U.S. Pat. Nos. 4,683,327A, 5,622,648A, 5,770,107A, WO1995/022586A, WO1995/024455A, WO1997/000600A, WO1998/023580A, WO1998/052905A, JP1989-272551A (JP-H1-272551A), JP1994-16616A (JP-H6-16616A), JP1995-110469A (JP-H7-110469A), JP1999-80081A (JP-H11-80081A), and JP2001-328973A can be used. Furthermore, as the rod-like liquid crystal compound in the other liquid crystal compounds, for example, compounds described in JP1999-513019B (JP-H11-513019B) or JP2007-279688A can be preferably used. As the disk-like liquid crystal compound in the other liquid crystal compounds, for example, compounds described in JP2007-108732A or JP2010-244038A can be preferably used.

The liquid crystal composition may include other liquid crystal compound alone, or may include two or more other liquid crystal compounds. From the viewpoint of suppressing change in reflectance and change in tint after molding, with respect to the total solid content of the liquid crystal composition, the content of the other liquid crystal compounds is preferably 70% by mass or less, more preferably 60% by mass or less, still more preferably 40% by mass or less, and particularly preferably 5% by mass or less. The lower limit value of the content of the other liquid crystal compounds is 0% by mass.

### —Chiral Agent (Optically Active Compound)—

From the viewpoint of ease of forming a cholesteric liquid crystal layer and ease of adjusting the pitch of the helical structure, the liquid crystal composition preferably includes a chiral agent (that is, an optically active compound). The chiral agent has a function of inducing a helical structure in the cholesteric liquid crystal layer. Since a twist direction or helical pitch of the helix induced by the chiral agent is different depending on the liquid crystal compound, the chiral agent may be selected according to the purpose. The chiral agent is not particularly limited, and a known compound (for example, a chiral agent for twisted nematic (TN) and super-twisted nematic (STN), compound described in “Liquid Crystal Device Handbook”, Chapter 3, Section 4-3, p. 199, Japan Society for the Promotion of Science edited by the 142nd committee, 1989), and an isosorbide or isomannide derivative can be used. The chiral agent generally includes an asymmetric carbon atom, but an axially asymmetric compound or a surface asymmetric compound, which does not have the asymmetric carbon atom, can also be used as the chiral agent. Preferred examples of the axially asymmetric compound or the surface asymmetric compound include a binaphthyl compound, a helicene compound, and a paracyclophane compound.

From the viewpoint of suppressing change in reflectance after molding, the liquid crystal composition preferably includes, as the chiral agent, a chiral agent having a polymerizable group, and more preferably includes, as the chiral agent, a chiral agent having a polymerizable group and a chiral agent not having a polymerizable group. The polymerizable group is not particularly limited as long as the group is polymerizable, but from the viewpoint of reactivity and viewpoint of suppressing change in reflectance after molding, the polymerizable group is preferably an ethylenically unsaturated group or a cyclic ether group, and more preferably an ethylenically unsaturated group. Preferred aspects of the ethylenically unsaturated group and cyclic ether group in the chiral agent are the same as the preferred aspects of the ethylenically unsaturated group and cyclic ether group in the above-described specific liquid crystal compound, respectively.

In a case where the chiral agent has an ethylenically unsaturated group or a cyclic ether group, from the viewpoint of reactivity and viewpoint of suppressing change in reflectance after molding, it is preferable that the ethylenically unsaturated group or cyclic ether group included in the specific liquid crystal compound has the same type of the ethylenically unsaturated group or cyclic ether group included in the chiral agent (for example, an ethylenically unsaturated group, preferably a (meth)acryloxy group), and it is more preferable to be the same group.

From the viewpoint of reactivity and viewpoint of suppressing change in reflectance after molding, the chiral agent having a polymerizable group is preferably a chiral agent having two or more polymerizable groups, more preferably a chiral agent having two or more ethylenically unsaturated groups or a chiral agent having two or more cyclic ether groups, and particularly preferably a chiral agent having two or more ethylenically unsaturated groups.

The chiral agent may be a cholesteric liquid crystal compound.

As will be described later, in a case of controlling a size of the helical pitch of the cholesteric liquid crystal layer by irradiating the cholesteric liquid crystal layer with light during manufacturing of the cholesteric liquid crystal layer, the liquid crystal composition preferably includes a chiral agent (hereinafter, also referred to as a “photosensitive chiral agent”) capable of changing the helical pitch of the cholesteric liquid crystal layer in response to light. The photosensitive chiral agent is a compound in which the structure can be changed by absorbing light, thereby being capable of changing the helical pitch of the cholesteric liquid crystal layer. As such a compound, a compound which causes at least one of a photoisomerization reaction, a photodimerization reaction, or a photodegradation reaction is preferable. The compound which causes a photoisomerization reaction refers to a compound which causes stereoisomerization or structural isomerization by the action of light. Examples of the compound which causes a photoisomerization reaction include an azobenzene compound and a spiropyran compound. In addition, the compound which causes a photodimerization reaction refers to a compound which causes an addition reaction between two groups so as to be cyclized by irradiation with light.

Examples of the compound which causes a photodimerization reaction include a cinnamic acid derivative, a coumarin derivative, a chalcone derivative, and a benzophenone derivative. In addition, the light is not particularly limited, and examples thereof include ultraviolet light, visible light, and infrared light.

Preferred examples of the photosensitive chiral agent include a chiral agent represented by Formula (CH1). The chiral agent represented by Formula (CH1) can change the alignment structure such as the helical pitch (for example, helical period and twist period) of a cholesteric liquid crystalline phase according to the amount of light during irradiation with the light.

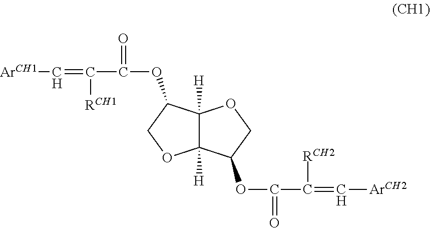

In Formula (CH1), Ar^{CH1} and Ar^{CH2} each independently represent an aryl group or a heteroaromatic ring group, and R^{CH1} and R^{CH2} each independently represent a hydrogen atom or a cyano group.

In Formula (CH1), it is preferable that Ar^{CH1} and Ar^{CH2} are each independently an aryl group. The aryl group of Ar^{CH1} and Ar^{CH2} in Formula (CH1) preferably has a total carbon number of 6 to 40, and more preferably has a total carbon number of 6 to 30. The aryl group may have a substituent. As the substituent, for example, a halogen atom, an alkyl group, an alkenyl group, an alkynyl group, an alkoxy group, a hydroxy group, an acyl group, an alkoxycarbonyl group, an aryloxycarbonyl group, an acyloxy group, a carboxy group, a cyano group, or a heterocyclic group is preferable, and a halogen atom, an alkyl group, an alkenyl group, an alkoxy group, a hydroxy group, an acyloxy group, an alkoxycarbonyl group, or an aryloxycarbonyl group is more preferable.

As Ar^{CH1} and Ar^{CH2}, an aryl group represented by Formula (CH2) or Formula (CH3) is preferable.

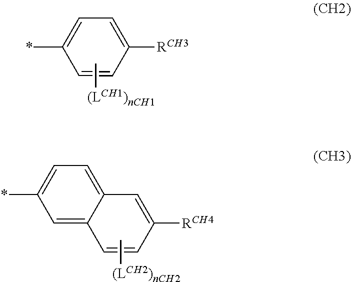

In Formula (CH2) and Formula (CH3), R^{CH3} and R^{CH4} each independently represent a hydrogen atom, a halogen atom, an alkyl group, an alkenyl group, an alkynyl group, an aryl group, a heterocyclic group, an alkoxy group, a hydroxy group, an acyl group, an alkoxycarbonyl group, an aryloxycarbonyl group, an acyloxy group, a carboxy group, or a cyano group, L^{CH1} and L^{CH2} each independently represent a halogen atom, an alkyl group, an alkoxy group, or a hydroxy group, nCH1 represents an integer of 0 to 4, nCH2 represents an integer of 0 to 6, and * represents a bonding position with C forming an ethylene unsaturated bond in Formula (CH1).

In Formula (CH2) and Formula (CH3), R^{CH3} and R^{CH4} are each independently preferably a hydrogen atom, a halogen atom, an alkyl group, an alkenyl group, an aryl group, an alkoxy group, a hydroxy group, an alkoxycarbonyl group, an aryloxycarbonyl group, or an acyloxy group, more preferably an alkoxy group, a hydroxy group, or an acyloxy group, and particularly preferably an alkoxy group.

In Formula (CH2) and Formula (CH3), L^{CH1} and L^{CH2} are each independently preferably an alkoxy group having 1 to 10 carbon atoms, or a hydroxy group.

nCH1 in Formula (CH2) is preferably 0 or 1.

nCH2 in Formula (CH3) is preferably 0 or 1.

The heteroaromatic ring group of Ar^{CH1} and Ar^{CH2} in Formula (CH1) preferably has a total carbon number of 4 to 40, and more preferably has a total carbon number of 4 to 30. The heteroaromatic ring group may have a substituent. As the substituent, for example, a halogen atom, an alkyl group, an alkenyl group, an alkynyl group, an aryl group, an alkoxy group, a hydroxy group, an acyl group, an alkoxycarbonyl group, an aryloxycarbonyl group, an acyloxy group, or a cyano group is preferable, and a halogen atom, an alkyl group, an alkenyl group, an aryl group, an alkoxy group, or an acyloxy group is more preferable. As the heteroaromatic ring group, a pyridyl group, a pyrimidinyl group, a furyl group, or a benzofuranyl group is preferable, and a pyridyl group or a pyrimidinyl group is more preferable.

In Formula (CH1), it is preferable that R^{CH1} and R^{CH2} are each independently a hydrogen atom.

The liquid crystal composition may include one chiral agent alone, or may include two or more chiral agents. A content of the chiral agent can be appropriately selected according to a desired pitch of the structure or a helical structure of the specific liquid crystal compound to be used. From the viewpoint of ease of forming a cholesteric liquid crystal layer and ease of adjusting the pitch of the helical structure, and viewpoint of suppressing change in reflectance after molding, the content of the chiral agent is preferably 1% by mass to 20% by mass, more preferably 2% by mass to 15% by mass, and particularly preferably 3% by mass to 10% by mass with respect to the total solid content of the liquid crystal composition.

In a case where the liquid crystal composition contains a chiral agent having a polymerizable group as the chiral agent, from the viewpoint of suppressing change in reflectance after molding, the content of the chiral agent having a polymerizable group is preferably 0.2% by mass to 15% by mass, more preferably 0.5% by mass to 10% by mass, still more preferably 1% by mass to 8% by mass, and particularly preferably 1.5% by mass to 5% by mass with respect to the total solid content of the liquid crystal composition.

In a case where the liquid crystal composition contains a chiral agent not having a polymerizable group as the chiral agent, from the viewpoint of suppressing change in reflectance after molding, the content of the chiral agent not having a polymerizable group is preferably 0.2% by mass to 20% by mass, more preferably 0.5% by mass to 15% by mass, and particularly preferably 1.5% by mass to 10% by mass with respect to the total solid content of the liquid crystal composition.

In addition, the pitch of the helical structure of the cholesteric liquid crystal in the cholesteric liquid crystal layer, and the selective reflection wavelength and its range described later can be easily changed not only by adjusting the type of the liquid crystal compound used but also by adjusting the content of the chiral agent. Although it cannot be said unconditionally, in a case where the content of the chiral agent in the liquid crystal composition is doubled, the above-described pitch may be halved and the center value of the above-described selective reflection wavelength may be halved.

### —Polymerization Initiator—

The liquid crystal composition preferably includes a polymerization initiator, and more preferably includes a photopolymerization initiator.

In a case where the liquid crystal composition includes a cholesteric liquid crystal compound having one ethylenically unsaturated group, from the viewpoint of suppressing change in reflectance and change in tint after molding, the above-described liquid crystal composition preferably includes a radical polymerization initiator, and more preferably includes a photoradical polymerization initiator.

In a case where the liquid crystal composition includes a cholesteric liquid crystal compound having one cyclic ether group, from the viewpoint of suppressing change in reflectance and change in tint after molding, the above-described liquid crystal composition preferably includes a cationic polymerization initiator, and more preferably includes a photocationic polymerization initiator.

It is preferable that the liquid crystal composition includes only one of the radical polymerization initiator or the cationic polymerization initiator as the polymerization initiator.

As the polymerization initiator, a known polymerization initiator can be used. In addition, the polymerization initiator is preferably a photopolymerization initiator capable of initiating a polymerization reaction by ultraviolet irradiation. Examples of the photopolymerization initiator include α-carbonyl compounds (described in U.S. Pat. Nos. 2,367,661A and 2,367,670A), acyloin ether compounds (described in U.S. Pat. No. 2,448,828A), α-hydrocarbon-substituted aromatic acyloin compounds (described in U.S. Pat. No. 2,722,512A), polynuclear quinone compounds (described in U.S. Pat. Nos. 3,046,127A and 2,951,758A), combinations of triarylimidazole dimer and p-aminophenyl ketone (described in U.S. Pat. No. 3,549,367A), acridine compounds and phenazine compounds (described in JP1985-105667A (JP-S60-105667A) and U.S. Pat. No. 4,239,850A), and oxadiazole compounds (described in U.S. Pat. No. 4,212,970A).

As the photoradical polymerization initiator, a known photoradical polymerization initiator can be used. Preferred examples of the photoradical polymerization initiator include α-hydroxyalkylphenone compounds, α-aminoalkylphenone compounds, and acylphosphine oxide compounds.

As the photocationic polymerization initiator, a known photocationic polymerization initiator can be used. Preferred examples of the photocationic polymerization initiator include iodonium salt compounds and sulfonium salt compounds.

The liquid crystal composition may include one polymerization initiator alone, or may include two or more polymerization initiators. A content of the polymerization initiator can be appropriately selected according to a desired pitch of the structure or helical structure of the specific liquid crystal compound to be used. From the viewpoint of ease of forming a cholesteric liquid crystal layer, ease of adjusting the pitch of the helical structure, a polymerization rate, and the strength of the cholesteric liquid crystal layer, the content of the polymerization initiator is preferably 0.05% by mass to 10% by mass, more preferably 0.05% by mass to 5% by mass, still more preferably 0.1% by mass to 2% by mass, and particularly preferably 0.2% by mass to 1% by mass with respect to the total solid content of the liquid crystal composition.

### —Crosslinking Agent—

The liquid crystal composition may include a crosslinking agent in order to improve the strength and durability of the cholesteric liquid crystal layer after curing. As the crosslinking agent, for example, a crosslinking agent which cures with ultraviolet rays, heat, or humidity can be suitably used. The crosslinking agent is not particularly limited and can be appropriately selected according to the purpose, and examples thereof include polyfunctional acrylate compounds such as trimethylolpropane tri(meth)acrylate and pentaerythritol tri(meth)acrylate; epoxy compounds such as glycidyl (meth)acrylate and ethylene glycol diglycidyl ether; aziridine compounds such as 2,2-bishydroxymethylbutanol-tris[3-(1-aziridinyl)propionate] and 4,4-bis(ethyleneiminocarbonylamino)diphenylmethane; isocyanate compounds such as hexamethylene diisocyanate and biuret-type isocyanate; polyoxazoline compounds having an oxazoline group in the side chain; and alkoxysilane compounds such as vinyltrimethoxysilane and N-(2-aminoethyl) 3-aminopropyltrimethoxysilane. In addition, a known catalyst can be used depending on reactivity of the crosslinking agent, and in addition to improving the strength and durability of the cholesteric liquid crystal layer, productivity can be improved.

The liquid crystal composition may include one crosslinking agent alone, or may include two or more crosslinking agents. From the viewpoint of the strength and durability of the cholesteric liquid crystal layer, a content of the crosslinking agent is preferably 1% by mass to 20% by mass and more preferably 3% by mass to 15% by mass with respect to the total solid content of the liquid crystal composition.

### —Polyfunctional Polymerizable Compound—

From the viewpoint of suppressing the change in reflectance after molding, the liquid crystal composition preferably includes a polyfunctional polymerizable compound and more preferably includes a polyfunctional polymerizable compound having the same type of polymerizable group. Examples of the polyfunctional polymerizable compound include, in the above-described other cholesteric liquid crystal compounds, cholesteric liquid crystal compounds having two or more ethylenically unsaturated groups and no cyclic ether group; cholesteric liquid crystal compounds having two or more cyclic ether groups and no ethylenically unsaturated group; cholesteric liquid crystal compounds having two or more ethylenically unsaturated groups and two or more cyclic ether groups; chiral agents having two or more polymerizable groups in the above-described chiral agent; and the above-described crosslinking agent.

In the liquid crystal composition, as the polyfunctional polymerizable compound, at least one compound selected from the group consisting of cholesteric liquid crystal compounds two or more ethylenically unsaturated groups and no cyclic ether group, cholesteric liquid crystal compounds having two or more cyclic ether groups and no ethylenically unsaturated group, and chiral agents having two or more polymerizable groups is preferable, and chiral agents having two or more polymerizable groups are more preferable.

The liquid crystal composition may include one polyfunctional polymerizable compound alone, or may include two or more polyfunctional polymerizable compounds. From the viewpoint of suppressing change in reflectance after molding, a content of the polyfunctional polymerizable compound is preferably 0.5% by mass to 70% by mass, more preferably 1% by mass to 50% by mass, still more preferably 1.5% by mass to 20% by mass, and particularly preferably 2% by mass to 10% by mass with respect to the total solid content of the liquid crystal composition.

### —Other Additives—

The liquid crystal composition may include other additives other than the above-described components as necessary. As other additives, a known additive can be used, and examples thereof include a surfactant, a polymerization inhibitor, an antioxidant, a horizontal alignment agent, an ultraviolet absorber, a light stabilizer, a colorant, and metal oxide particles.

In addition, the liquid crystal composition may include a solvent. The solvent is not particularly limited and can be appropriately selected according to the purpose, but an organic solvent is preferably used. The organic solvent is not particularly limited and can be appropriately selected according to the purpose, and examples thereof include ketones (for example, methyl ethyl ketone and methyl isobutyl ketone), alkyl halides, amides, sulfoxides, heterocyclic compounds, hydrocarbons, esters, and ethers. The solvent may be used singly, or two or more kinds thereof may be used in combination. Among these, in consideration of environmental load, ketones are particularly preferable. In addition, the above-described component may function as the solvent.

A content of the solvent in the liquid crystal composition is not particularly limited, and may be adjusted to a content of the solvent such that desired coating properties are obtained. A content of solid contents with respect to the total mass of the liquid crystal composition is not particularly limited, but is preferably 1% by mass to 90% by mass, more preferably 5% by mass to 80% by mass, and particularly preferably 10% by mass to 80% by mass. The content of the solvent in the liquid crystal composition during curing in a case of forming the cholesteric liquid crystal layer is preferably 5% by mass or less, more preferably 3% by mass or less, still more preferably 2% by mass or less, and particularly preferably 1% by mass or less with respect to the total solid content of the liquid crystal composition. In addition, the content of the solvent in the cholesteric liquid crystal layer obtained by curing the liquid crystal composition is preferably 5% by mass or less, more preferably 3% by mass or less, still more preferably 2% by mass or less, and particularly preferably 1% by mass or less with respect to the total mass of the cholesteric liquid crystal layer.

### —Coating and Curing of Liquid Crystal Composition—

In the formation of the cholesteric liquid crystal layer, for example, the liquid crystal composition is used by being applied to an object (for example, the above-described base material, and an alignment layer described later). After the liquid crystal composition is made into a solution with a solvent or made into a liquid such as a molten liquid by heating, the liquid crystal composition can be applied, for example, by an appropriate method such as a roll coating method, a gravure printing method, and a spin coating method. The liquid crystal composition can also be applied by various methods such as a wire bar coating method, an extrusion coating method, a direct gravure coating method, a reverse gravure coating method, and a die-coating method. In addition, using an inkjet device, the liquid crystal composition can be jetted from a nozzle to form a coating film (referring to a film-like liquid crystal composition formed by coating).

After the application of the liquid crystal composition, the cholesteric liquid crystal layer is formed by curing the liquid crystal composition. By curing the liquid crystal composition, the alignment state of molecules of the liquid crystal compound (for example, the above-described specific liquid crystal compound) is maintained and fixed. The curing of the liquid crystal composition is preferably performed by a polymerization reaction of polymerizable groups (for example, ethylenically unsaturated groups or cyclic ether groups) included in the liquid crystal compound. In a case of using the solvent as a component of the liquid crystal composition, after the application of the liquid crystal composition and before the polymerization reaction for curing, it is preferable that the coating film is dried by a known method. For example, the coating film may be dried by allowing it to stand or by heating. It is sufficient that the liquid crystal compound in the liquid crystal composition is aligned after the application and drying of the liquid crystal composition.

### —Layer Configuration of Cholesteric Liquid Crystal Layer—

From the viewpoint of suppressing change in reflectance after molding, the decorative film according to one embodiment of the present disclosure preferably includes two or more cholesteric liquid crystal layers. In addition, compositions of the two or more cholesteric liquid crystal layers may be the same or different from each other. In a case where the decorative film according to one embodiment of the present disclosure includes two or more cholesteric liquid crystal layers, it is sufficient that the decorative film according to one embodiment of the present disclosure has at least one layer formed by curing a liquid crystal composition which includes, with respect to the total solid content of the liquid crystal composition, 25% by mass or more of the cholesteric liquid crystal compound having one ethylenically unsaturated group or one cyclic ether group (that is, the specific liquid crystal compound). From the viewpoint of suppressing change in reflectance after molding, it is preferable that all the two or more cholesteric liquid crystal layers are a layer formed by curing a liquid crystal composition which includes, with respect to the total solid content of the liquid crystal composition, 25% by mass or more of the cholesteric liquid crystal compound having one ethylenically unsaturated group or one cyclic ether group.

In addition, for example, in a case where the decorative film according to one embodiment of the present disclosure has two cholesteric liquid crystal layers, from the viewpoint of suppressing change in reflectance after molding, it is preferable to have the cholesteric liquid crystal layer on each surface of the above-described base material.

### <<Selective Reflectivity of Reflective Layer>>

The reflective layer has a region having a reflectivity of at least 5% or more. In the present disclosure, the reflectivity and the transmittance are measured using a spectrophotometer (for example, a spectrophotometer UV-2100 manufactured by Shimadzu Corporation, a spectrophotometer V-670 of JASCO Corporation, and the like).

It is preferable to have a region having a reflectivity of at least 8% or more and 40% or less in a wavelength range of 380 nm or more and 800 nm or less. From the viewpoint of visibility of the decorative film, it is more preferably 10% or more and 35% or less, and still more preferably 15% or more and 30% or less.

The decorative film according to one embodiment of the present disclosure has a total light transmittance of 50% or more in a wavelength range of 380 nm or more and 800 nm or less. From the viewpoint of obtaining decoration visibility, decoration texture, and smooth touch, it is preferably 60% or more, more preferably 65% or more, still more preferably 70% or more, and particularly preferably 80% or more.

### <Alignment Layer>

The decorative film according to one embodiment of the present disclosure may include an alignment layer which is in contact with the cholesteric liquid crystal layer. The alignment layer is used for aligning the molecules of the liquid crystal compound in the liquid crystal composition in a case of forming a layer including the liquid crystal compound (hereinafter, also referred to as a “liquid crystal layer”). For example, since the alignment layer is used in the case of forming the liquid crystal layer, in a decorative film which does not include the liquid crystal layer, the alignment layer may or may not be included.

For example, the alignment layer can be provided by a rubbing treatment of an organic compound (preferably a polymer), an oblique vapor deposition of an inorganic compound (for example, SiO₂), or a formation of a layer having a microgroove. Furthermore, an alignment layer in which an alignment function occurs by application of an electric field, application of a magnetic field, or light irradiation has also been known. Depending on a material of the underlayer such as the support and the liquid crystal layer, the alignment layer may not be provided and the underlayer may be subjected to a direct alignment treatment (for example, rubbing treatment) to function as an alignment layer. Polyethylene terephthalate (PET) can be mentioned as an example of such a support as the underlayer. In addition, in a case where a layer (hereinafter, referred to as an “upper layer” in this paragraph) is directly laminated on the liquid crystal layer, in some cases, the liquid crystal layer as the underlayer behaves as the alignment layer and the liquid crystal compound for forming the upper layer can be aligned. In such a case, the liquid crystal compound in the upper layer can be aligned without providing the alignment layer or performing a special alignment treatment (for example, rubbing treatment).

Hereinafter, as a preferred example of the alignment layer, a rubbing-treated alignment layer and a photoalignment layer will be described.

### <<Rubbing-Treated Alignment Layer>>

The rubbing-treated alignment layer is an alignment layer to which aligning properties are imparted by a rubbing treatment. Examples of a polymer which can be used in the rubbing-treated alignment layer include a methacrylate-based copolymer, a styrene-based copolymer, polyolefin, polyvinyl alcohol and modified polyvinyl alcohol, poly(N-methylol acrylamide), polyester, polyimide, a vinyl acetate copolymer, carboxymethyl cellulose, and polycarbonate, which are described in paragraph 0022 of JP1996-338913A (JP-H8-338913A). A silane coupling agent can be used as the polymer. As the polymer which can be used in the rubbing-treated alignment layer, a water-soluble polymer (for example, poly(N-methylol acrylamide), carboxymethyl cellulose, gelatin, polyvinyl alcohol, and modified polyvinyl alcohol) is preferable, gelatin, polyvinyl alcohol, or modified polyvinyl alcohol is more preferable, and polyvinyl alcohol or modified polyvinyl alcohol is particularly preferable.

In a method of aligning the liquid crystal compound using the rubbing-treated alignment layer, for example, the molecules of the liquid crystal compound are aligned by coating a rubbing-treated surface of the rubbing-treated alignment layer with a composition for forming a cholesteric liquid crystal layer (one aspect of the liquid crystal composition). Thereafter, as necessary, by reacting the polymer included in the alignment layer with a polyfunctional monomer included in the cholesteric liquid crystal layer, or by crosslinking polymer included in the alignment layer using a crosslinking agent, the cholesteric liquid crystal layer can be formed. A film thickness of the alignment layer is preferably in a range of 0.1 μm to 10 μm.

### —Rubbing Treatment—

The surface of the alignment layer, the support, or other layers, to be coated with the composition for forming a cholesteric liquid crystal layer, may be subjected to a rubbing treatment as necessary. The rubbing treatment can be generally performed by rubbing a surface of a film containing a polymer as a main component with paper or cloth in a certain direction. The general method of the rubbing treatment is described in, for example, “Handbook of Liquid crystals” (published by Maruzen, Oct. 30, 2000).

As a method of changing a rubbing density, the method described in “Handbook of Liquid crystals” (published by Maruzen) can be used. The rubbing density (L) is quantified by Expression (A).

$$L = N 1 ( 1 + 2 π rn / 60 v ) \qquad Expression ( A )$$

In Expression (A), N is the number of times of rubbing, l is a contact length of a rubbing roller, π is a circumference ratio, r is a radius of the roller, n is a rotation speed (rpm) of the roller, and v is a stage moving speed (speed per second).

In order to increase the rubbing density, it is sufficient that the number of times of rubbing is increased, the contact length of the rubbing roller is increased, the radius of the roller is increased, the rotation speed of the roller is increased, or the stage moving speed is decreased. On the other hand, in order to decrease the rubbing density, it is sufficient that the reverse is carried out. In addition, with regard to conditions for the rubbing treatment, the description in JP4052558B can be referred to.

### <<Photoalignment Layer>>

The photoalignment layer is an alignment layer to which aligning properties are imparted by light irradiation. A photo-alignment material used for the photoalignment layer is described in many references. Preferred examples of the photo-alignment material include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; aromatic ester compounds described in JP2002-229039A; maleimide and/or alkenyl-substituted nadiimide compounds having a photo alignment unit, described in JP2002-265541A and JP2002-317013A; photo-crosslinkable silane derivatives described in JP4205195B and JP4205198B; and photo-crosslinkable polyimides, polyamides, or esters described in JP2003-520878A, JP2004-529220A, and JP4162850B. Azo compounds or photo-crosslinkable polyimides, polyamides, or esters are particularly preferable.

For example, the photoalignment layer is manufactured by subjecting a layer formed of the above-described material to an irradiation of linearly polarized light or non-polarized light. In the present disclosure, the “irradiation of linearly polarized light” is an operation for causing a photo-reaction of the photo-alignment material. The wavelength of the light used depends on the photo-alignment material used, and is not particularly limited as long as a wavelength is necessary for the photo-reaction. The peak wavelength of the light used for light irradiation is preferably 200 nm to 700 nm and the light is more preferably ultraviolet light having a peak wavelength of 400 nm or less.

Examples of a light source used for light irradiation include commonly used light sources, for example, lamps (for example, a tungsten lamp, a halogen lamp, a xenon lamp, a xenon flash lamp, a mercury lamp, a mercury-xenon lamp, and a carbon arc lamp), various lasers (for example, semiconductor laser, helium neon laser, argon ion laser, helium cadmium laser, and yttrium aluminum garnet (YAG) laser), light emitting diodes, and cathode ray tube.

As a method for obtaining the linearly polarized light, a method of using a polarizing plate (for example, iodine polarizing plate, dichroic coloring agent polarizing plate, and wire grid polarizing plate), a method of using a prismatic element (for example, Glan-Thompson prism) and a reflective type polarizer using Brewster's angle, or a method of using light emitted from a polarized laser light source can be adopted. In addition, by using a filter and a wavelength conversion element, only light having a required wavelength may be irradiated selectively.

In a case where the irradiated light is the linearly polarized light, a method of irradiating light perpendicularly or obliquely to the upper surface or the lower surface of the alignment layer is adopted. The incidence angle of the light varies depending on the photo-alignment material, but is preferably 0° to 90° (perpendicular) and more preferably 40° to 90°. In a case where non-polarized light is used, the non-polarized light is obliquely irradiated to the upper surface or the lower surface of the alignment layer. The incidence angle of the non-polarized light is preferably 10° to 80°, more preferably 20° to 60°, and particularly preferably 30° to 50°. The irradiation time is preferably 1 minute to 60 minutes and more preferably 1 minute to 10 minutes.

### <Layer Having Convex Structure>

The decorative film according to one embodiment of the present disclosure includes a layer having a convex structure with a height of at least 1 μm or more on an outermost surface (hereinafter, also referred to as “coating layer”).

A shape of the above-described convex structure is not particularly limited, and examples thereof include various shapes such as a hemispherical shape, a semi-elliptical shape, a pyramidal shape, a truncated pyramidal shape, a conical shape, a truncated conical shape. The shape of the above-described convex structure in a plane direction is not particularly limited, and examples thereof include various shapes such as a linear structure, a spiral structure, a concentric circular structure, a wavy linear structure, an array structure, and a random structure.

In addition, a cross-sectional shape of the above-described convex structure is also not particularly limited, and examples thereof include an aspect in which the cross-sectional shape in a direction perpendicular to the plane direction of the decorative sheet and a direction perpendicular to the longitudinal direction of the convex structure has various shapes such as triangular, trapezoidal, semicircular, semielliptical, and rounded triangular (for example, the cross-sectional shape is a shape of one period of a trigonometric function).

In addition, examples of the above-described convex structure also include a linear convex structure in which convex structures are arranged in one direction (for example, a prism shape (the cross-sectional shape is triangular), a lenticular shape (the cross-sectional shape is semi-circular), a curve shape (the cross-sectional shape is wavy), and the like). Among these, the convex structure in the above-described layer having a convex structure is preferably a convex structure randomly disposed in the plane.

From the viewpoint of obtaining decoration visibility, decoration texture, and smooth touch, the height of the convex structure is preferably 3 μm or more and less than 50 μm, and more preferably 5 μm or more and less than 30 μm. In the present disclosure, a height difference between adjacent local maximum portion and local minimum portion of a convex surface, obtained using a laser microscope (for example, VK-XX1000 manufactured by KEYENCE CORPORATION), is adopted as the height of the convex structure.

From the viewpoint of obtaining decoration visibility, decoration texture, and smooth touch, a width of the convex structure is preferably 5 μm or more, more preferably 10 μm to 200 μm, still more preferably 20 μm to 100 μm, and particularly preferably 30 μm to 80 μm. In the present disclosure, a distance between adjacent local minimum portion and local minimum portion of a convex surface, obtained using a laser microscope (for example, VK-X1000 manufactured by KEYENCE CORPORATION), is adopted as the width of the convex structure.

From the viewpoint of visual recognition of uniform tint regardless of viewing angle, and lustrousness, a ratio (width:depth) of the width of the convex structure and the depth of the convex structure is preferably 100:1 to 1:2 and more preferably 50:1 to 1:1.

The number of convex structures having a height of 1 μm or more within an area of 200 μm² in the above-described layer having a convex structure is preferably 5 or more and 200 or less, more preferably 10 or more and 100 or less, and still more preferably 15 or more and 80 or less. In the above-described range, a decorative film which has excellent visibility of decoration, has high design texture, and has a smooth tactile sensation can be obtained.

In the decorative film according to one embodiment of the present disclosure, it is preferable that at least a part of the convex structure has a height of 5 μm or more. It is preferable that the decorative film according to one embodiment of the present disclosure includes both convex structures in which at least a part of the convex structure has a height of 5 μm or more and at least a part of the convex structure has a height of less than 5 μm. The number of convex structures having a height of less than 5 μm within an area of 200 μm² is preferably 10 or more and 500 or less, more preferably 20 or more and 300 or less, and still more preferably 30 or more and 150 or less. In the above-described range, a decorative film which has excellent visibility of decoration, has high design texture, and has a smooth tactile sensation can be obtained.

In the decorative film according to one embodiment of the present disclosure, it is preferable that at least a part of the convex structure has light absorbability. In the decorative film according to one embodiment of the present disclosure, it is more preferable that at least a part of the convex structure has a property of absorbing light having a wavelength of 300 nm to 780 nm. Specific examples thereof include an aspect in which the convex structure contains a colorant. By having the property of absorbing light having a wavelength of 300 nm to 780 nm, since it is possible to suppress scattering of the convex structure with respect to light exposed from the external environment such as sunlight and fluorescent lamp or with respect to light emitted from a display device in a case where the decorative film according to the embodiment of the present disclosure is disposed on a display device, while maintaining a smooth tactile sensation, it is possible to improve the visibility of decoration and the visibility of a light source in a case where the light source is installed on the back surface.

A method of forming the convex structure having a height of 1 μm or more is not particularly limited, and examples thereof include a method in which a mold with a shape corresponding to the convex structure (hereinafter, referred to as “convex shape” in this paragraph) is formed in advance is produced, and the convex shape is transferred to a base material on which a resin layer not having the convex structure is laminated, or to a base material; a method of coating or printing a layer containing particles having an average particle diameter of 1 μm or more on a film surface to form the convex structure; and a method of forming the convex structure using printing, photolithography, or the like. In the present disclosure, the method of coating or printing a layer containing particles having an average particle diameter of 1 μm or more on a film surface to form the convex shape is most preferable.

Examples of the method in which a mold with a shape corresponding to the convex structure is formed is produced, and the convex shape is transferred to a base material on which a resin layer not having the convex structure is laminated include a step of bringing the resin layer not having the convex structure into contact with a mold surface having the convex structure, and applying pressure thereto, in which the resin layer may be brought close to the mold surface having the convex structure or the surface having the convex structure may be brought close to the resin layer. The reflective layer may be brought into contact with the surface having a convex structure through another layer (for example, an alignment layer).

The pressure applied to the resin layer not having the convex structure is preferably 0.1 MPa or more, more preferably 0.3 MPa or more, and particularly preferably 0.5 MPa or more. The upper limit of the pressure applied to the reflective layer is not limited. The upper limit of the pressure applied to the reflective layer may be determined, for example, in accordance with workability of the reflective layer and the thickness of the decorative film. The pressure applied to the reflective layer is preferably 10 MPa or less, more preferably 3 MPa or less, and particularly preferably 1 MPa or less.

Examples of the method of coating or printing the layer containing particles having an average particle diameter of 1 μm or more on the film surface include coating using a bar or Giesser, and printing such as screen printing, gravure printing, and offset printing.

### <<Particles>>

From the viewpoint of easily forming the convex structure of the surface, it is preferable that the layer containing particles having an average particle diameter of 1 μm or more contains at least particles having a diameter of 1 μm or more. By setting the average particle diameter to 1 μm or more, visibility of the decorative film is high, visibility of a light source in a case where the light source is installed on the back surface is high, and a pleasant tactile sensation in a case of touching the surface of the decorative film is provided. It is more preferable to contain particles having a diameter of 2 μm or more and 100 μm or less, still more preferable to contain particles having a diameter of 3 μm or more and 50 μm or less, and particularly preferable to contain particles having a diameter of 5 μm or more and 30 μm or less.

As the particles, translucent particles are preferably used. Preferred specific examples thereof include resin particles such as poly((meth)acrylate) particles, crosslinked poly((meth)acrylate) particles, polystyrene particles, crosslinked polystyrene particles, crosslinked poly(acrylic-styrene) particles, melamine resin particles, and benzoguanamine resin particles. Among these, crosslinked polystyrene particles, crosslinked poly((meth)acrylate) particles, or crosslinked poly(acrylic-styrene) particles are preferably used, and by adjusting a refractive index of a translucent resin according to a refractive index of each translucent particle selected from these particles, inside haze, surface haze, and centerline average roughness can be achieved. Specifically, a combination of a translucent resin in which a main component is a tri- or higher functional (meth)acrylate monomer as described later (refractive index after curing: 1.50 to 1.53) and translucent particles consisting of a crosslinked poly(meth)acrylate-based polymer having an acrylic content of 50% by mass to 100% by mass is preferable, and a combination of the translucent resin and translucent particles consisting of a crosslinked poly(styrene-acrylic) copolymer having a styrene content of 1% by mass to 100% by mass (refractive index: 1.48 to 1.54) is particularly preferable.

In addition, two or more kinds of translucent particles having different particle diameters may be used in combination. It is possible to impart anti-glare characteristic with the translucent particles having a larger particle diameter, and to reduce feeling of surface roughness with the translucent particles having a smaller particle diameter.

The refractive index of the translucent resin and the translucent particles in the present disclosure is preferably 1.45 to 1.70 and more preferably 1.48 to 1.65. In order to set the refractive index within the above-described range, the types and amount proportions of the translucent resin and the translucent particles may be appropriately selected. It is possible to easily know about the selection in advance experimentally.

In addition, in the present disclosure, an absolute value of a difference in refractive index between the translucent resin and the translucent particles (refractive index of the translucent particles−refractive index of the translucent resin) is preferably 0.001 to 0.030, more preferably 0.001 to 0.020, and still more preferably 0.001 to 0.015. Within the above-described range, problems such as blurriness of film character, a decrease in dark room contrast, and surface turbidity do not occur.

Here, the refractive index of the above-described translucent resin can be quantitatively evaluated by directly measuring the refractive index with an Abbe refractometer or measuring the refractive index with a spectral reflection spectrum or a spectral ellipsometry. The refractive index of the above-described translucent particles is obtained by dispersing an equal amount of the translucent particles in a solvent in which the refractive index is changed by changing a mixing ratio of two types of solvents with different refractive indexes to measure turbidity, and measuring a refractive index of the solvent in a case where the turbidity reaches its minimum using an Abbe refractometer.

The above-described translucent particles are blended in the formed layer having the convex structure described above so that the translucent particles are contained in an amount of 3% by mass to 30% by mass in the total solid content of the layer having the convex structure described above. It is more preferably 5% to 20% by mass. In a case of being 3% by mass or more, sufficient anti-glare characteristic can be obtained, and in a case of being 30% by mass or less, problems such as image blur, surface turbidity, and glare do not occur.

In addition, a density of the translucent particles is preferably 10 mg/m² to 1,000 mg/m² and more preferably 100 mg/m² to 700 mg/m².

A film thickness of the above-described layer having the convex structure is preferably 1 μm to 10 μm and more preferably 1.2 μm to 8 μm. Within the above-described range, strength is excellent, curl and brittleness are sufficient, and workability is excellent.

### <Translucent Resin>

The translucent resin is preferably a binder polymer having a saturated hydrocarbon chain or a polyether chain as a main chain, and more preferably a binder polymer having a saturated hydrocarbon chain as a main chain. In addition, the binder polymer preferably has a crosslinking structure.

As the binder polymer having a saturated hydrocarbon chain as a main chain, a polymer of an ethylenically unsaturated monomer is preferable. As the binder polymer having a saturated hydrocarbon chain as a main chain and having a crosslinking structure, a (co)polymer of a monomer having two or more ethylenically unsaturated groups is preferable.

In order to make the binder polymer have a high refractive index, a high refractive index monomer including an aromatic ring or at least one atom selected from a halogen atom other than fluorine, a sulfur atom, a phosphorus atom, and a nitrogen atom in the structure of the monomer, or a monomer having a fluorene skeleton in the molecule can also be selected.

Examples of the monomer having two or more ethylenically unsaturated groups include polyfunctional monomers containing two or more polymerizable reactive functional groups, for example, an ester of a polyhydric alcohol and (meth)acrylic acid [such as ethylene glycol di(meth)acrylate, butanediol di(meth)acrylate, hexanediol di(meth)acrylate, 1,4-cyclohexane diacrylate, pentaerythritol tetra(meth)acrylate, pentaerythritol tri(meth)acrylate, trimethylolpropane tri(meth)acrylate, trimethylol ethanetri(meth)acrylate, dipentaerythritol tetra(meth)acrylate, dipentaerythritol penta(meth)acrylate, dipentaerythritol hexa(meth)acrylate, pentaerythritol hexa(meth)acrylate, 1,2,3-cyclohexane tetramethacrylate, polyurethane polyacrylate, and polyester polyacrylate], ethylene oxide-modified products and caprolactone-modified products of the ester, vinylbenzene and derivatives thereof [such as 1,4-divinylbenzene, 4-vinylbenzoic acid-2-acryloylethyl ester, and 1,4-divinylcyclohexanone], vinyl sulfone (such as divinyl sulfone), acrylamide (such as methylene bisacrylamide), and methacrylamide. The above-described monomers may be used in combination of two or more kinds thereof. Among these, a tri- or higher functional (meth)acrylate monomer is preferable.

Specific examples of the high refractive index monomer include (meth)acrylates having a fluorene skeleton, bis(4-methacryloylthiophenyl)sulfide, vinylnaphthalene, vinyl phenyl sulfide, and 4-methacryloxyphenyl-4′-methoxyphenylthioether. These monomers may also be used in combination of two or more kinds thereof.

The polymerization of the monomer having an ethylenically unsaturated group can be carried out by irradiation with ionizing radiation or by heating in the presence of a photo-radical initiator or a thermal radical initiator.

Accordingly, the above-described layer having the convex structure can be formed by preparing a coating liquid containing a monomer for forming the translucent resin, such as the above-described ethylenically unsaturated monomer, a photo-radical initiator or a thermal radical initiator, the translucent particles, and an inorganic filler as necessary, which will be described later, and applying the coating liquid onto a transparent support and then curing the coating liquid by a polymerization reaction using ionizing radiation or heat.

Examples of the photo-radical (polymerization) initiator include acetophenones, benzoins, benzophenones, phosphine oxides, ketals, anthraquinones, thioxanthones, azo compounds, peroxides, 2,3-dialkyldione compounds, disulfide compounds, fluoroamine compounds, and aromatic sulfoniums. Examples of the acetophenones include 2,2-diethoxyacetophenone, p-dimethylacetophenone, 1-hydroxydimethylphenylketone, 1-hydroxycyclohexylphenylketone, 2-methyl-4-methylthio-2-morpholinopropiophenone, and 2-benzyl-2-dimethylamino-1-(4-morpholinophenyl)-butanone. Examples of the benzoins include benzoin benzenesulfonic acid ester, benzoin toluenesulfonic acid ester, benzoin methyl ether, benzoin ethyl ether, and benzoin isopropyl ether. Examples of the benzophenones include benzophenone, 2,4-dichlorobenzophenone, 4,4-dichlorobenzophenone, and p-chlorobenzophenone. Examples of the phosphine oxides include 2,4,6-trimethylbenzoyldiphenylphosphine oxide.

Preferred examples of a commercially available photocleavage type photo-radical (polymerization) initiator include IRGACURE 651, IRGACURE 184, and IRGACURE 907 manufactured by BASF.

The photo-radical (polymerization) initiator is preferably used in a range of 0.1 parts by mass to 15 parts by mass and more preferably used in a range of 1 part by mass to 10 parts by mass with respect to 100 parts by mass of the polyfunctional monomer.

In addition to the photo-radical (polymerization) initiator, a photosensitizer may be used. Specific examples of the photosensitizer include n-butylamine, triethylamine, tri-n-butylphosphine, Michler's ketone, and thioxanthone.

As the thermal radical initiator, an organic or inorganic peroxide, an organic azo compound, a diazo compound, or the like can be used.

Specific examples thereof include, as the organic peroxide, benzoyl peroxide, halogen benzoyl peroxide, lauroyl peroxide, acetyl peroxide, dibutyl peroxide, cumene hydroperoxide, and butyl hydroperoxide; as the inorganic peroxide, hydrogen peroxide, ammonium persulfate, potassium persulfate, and the like; as the azo compound, 2-azo-bis-isobutyronitrile, 2-azo-bis-propionitrile, 2-azo-bis-cyclohexane dinitrile, and the like; and as the diazo compound, diazoaminobenzene, p-nitrobenzene diazonium, and the like.

As the binder polymer having a polyether as a main chain, a ring-opening polymer of a polyfunctional epoxy compound is preferable. A ring-opening polymerization of the polyfunctional epoxy compound can be carried out by irradiation with ionizing radiation or by heating in the presence of a photoacid generator or a thermal acid generator.

Accordingly, the above-described layer having the convex structure can be formed by preparing a coating liquid containing the polyfunctional epoxy compound, a photoacid generator or a thermal acid generator, the translucent particles, and an inorganic filler, and applying the coating liquid onto a transparent support and then curing the coating liquid by a polymerization reaction using ionizing radiation or heat.

The crosslinking structure may be introduced into the binder polymer by a method in which, instead of or in addition to the monomer having two or more ethylenically unsaturated groups, a crosslinking functional group is introduced into the polymer using a monomer having the crosslinking functional group, and this crosslinking functional group is reacted.

Examples of the crosslinking functional group include an isocyanate group, an epoxy group, an aziridine group, an oxazoline group, an aldehyde group, a carbonyl group, a hydrazine group, a carboxyl group, a methylol group, and an active methylene group. Vinylsulfonic acids, acid anhydrides, cyanoacrylate derivatives, melamines, etherified methylols, esters, urethanes, or metal alkoxides such as tetramethoxysilane can also be used as the monomer for introducing the crosslinking structure. A functional group which exhibits crosslinkability as a result of a decomposition reaction, such as a blocked isocyanate group, may be used. That is, in the present invention, the crosslinking functional group may not exhibit reaction immediately, but may exhibit reactivity as a result of decomposition.

These binder polymers having a crosslinking functional group can be heated after the application to form a crosslinking structure.

In order to adjust the refractive index of the layer to reduce the haze value due to internal scattering, the above-described layer having the convex structure may contain, in addition to the above-described translucent particles, an inorganic filler which consists of an oxide of at least one metal selected from silicon, titanium, zirconium, aluminum, indium, zinc, tin, and antimony, and has an average particle diameter of 0.2 μm or less, preferably 0.1 μm or less and more preferably 0.06 μm or less. Since these inorganic fillers have a specific gravity higher than that of an organic filler and can increase a density of a coating composition, these inorganic fillers also have an effect of slowing a sedimentation velocity of the translucent particles.

It is also preferable that a surface of the inorganic filler used in the above-described layer having the convex structure is subjected to a silane coupling treatment or a titanium coupling treatment, and a surface treatment agent having a functional group, which is capable of reacting with the binder species on the filler surface, is preferably used.

In a case where these inorganic fillers are used, an addition amount thereof is preferably 10% by mass to 90% by mass, more preferably 20% by mass to 80% by mass, and particularly preferably 30% by mass to 75% by mass with respect to the total mass of the above-described layer having the convex structure.

Such an inorganic filler does not cause scattering because the particle diameter thereof is sufficiently smaller than the wavelength of light, and a dispersion in which the filler is dispersed in the binder polymer behaves as an optically uniform substance.

The decorative film according to one embodiment of the present disclosure preferably contains coloring particles, and more preferably contains black particles. By containing the coloring particles, since it is possible to suppress scattering of the convex portion with respect to light exposed from the external environment such as sunlight and fluorescent lamp or with respect to light emitted from a display device in a case where the decorative film according to the embodiment of the present disclosure is disposed on a display device, while maintaining a smooth tactile sensation, it is possible to improve the visibility of decoration and the visibility of a light source in a case where the light source is installed on the back surface.

In addition, from the viewpoint of decoration visibility, and visibility of light source in a case where the back surface display is turned on, it is preferable that the above-described coloring particles are contained in the above-described layer having the convex structure.

Furthermore, from the viewpoint of decoration visibility, and visibility of light source in a case where the back surface display is turned on, the above-described black particles are preferably black resin particles and more preferably black acrylic resin particles.

Examples of the coloring particles include particles containing a pigment or a dye in resin particles such as poly((meth)acrylate) particles, crosslinked poly((meth)acrylate) particles, polystyrene particles, crosslinked polystyrene particles, crosslinked poly(acrylic-styrene) particles, melamine resin particles, and benzoguanamine resin particles.

Preferred examples of commercially available coloring particles include Micropearl 50395 (average particle diameter: 3.95 μm), 506 (average particle diameter: 6 μm), 508 (average particle diameter: 8 μm), 512 (average particle diameter: 12 μm), and 515 (average particle diameter: 15 μm) manufactured by SEKISUI CHEMICAL CO., LTD.

### <<Surfactant for Layer Having Convex Structure Described Above>>

In order to particularly secure surface uniformity such as coating unevenness, drying unevenness, and point defect, the above-described layer having the convex structure preferably contains a fluorine-based surfactant, a silicone-based surfactant, or both surfactants in a coating composition for forming the above-described layer having the convex structure. In particular, the fluorine-based surfactant is preferably used because a smaller amount of the surfactant to be added has an effect of improving surface defects such as coating unevenness, drying unevenness, and point defect of the decorative film according to the embodiment of the present disclosure.

### <λ/4 Phase Difference Plate>

The decorative film according to one embodiment of the present disclosure preferably includes a λ/4 phase difference plate.

It is preferable that the λ/4 phase difference plate is disposed on a side of the reflective layer opposite to an uneven structure having a depth of at least 1 μm or more on the outermost surface. By including the λ/4 phase difference plate, the decorative film can be used as a highly applicable decorative member. The “λ/4 phase difference plate” is a plate having a λ/4 function, specifically, a plate having a function of converting linearly polarized light having a specific wavelength into circularly polarized light (or converting circularly polarized light into linearly polarized light).

For example, in a case where a surface of a liquid crystal display element (display) is decorated with the decorative film including the λ/4 phase difference plate, decoration having unique designability can be realized where the color of the decorative sheet is seen only during turn-off of the display or black display and the decorative sheet is transparent and has no presence during white display. That is, with the liquid crystal display device in which a composite film including the decorative film and the λ/4 phase difference plate is provided on a surface (image display surface), the liquid crystal display device having unique designability can be realized where the color of the decorative film is seen only during turn-off of the display or black display and the decorative sheet is transparent and has no presence during white display.

In addition, the decorative film including the λ/4 phase difference plate can also be utilized as a reflection plate such as a reflective liquid crystal display element or a semi-transmissive liquid crystal liquid crystal display element.

The decorative film can be used as an automobile interior material using the above-described unique designability. In addition, the decorative film including the λ/4 phase difference plate is not limited to this use and can be used in various uses to prevent an article applied to decoration from being reflected on a reflector.

Specific examples of the λ/4 phase difference plate include US2015/0277006A.

For example, specific examples of an aspect in which the λ/4 phase difference plate has a monolayer structure include a stretched polymer film and a retardation film in which an optically-anisotropic layer having λ/4 function is provided on a support. In addition, specific examples of an aspect in which the λ/4 phase difference plate has a multilayer structure include a broadband λ/4 phase difference plate where a λ/4 phase difference plate and a λ/2 phase difference plate are laminated. The λ/4 phase difference plate can be formed, for example, by applying a liquid crystal composition including a liquid crystal compound. It is more preferable that the λ/4 phase difference plate is a retardation film including one or more layers including at least one liquid crystal compound (such as a disk-like liquid crystal compound or a rod-like liquid crystal compound) formed by polymerizing a liquid crystal monomer exhibiting a nematic liquid crystal layer or a smectic liquid crystal layer.

In addition, it is still more preferable to use a liquid crystal compound having reverse wavelength dispersibility as the λ/4 phase difference plate having excellent optical performance. Specifically, a liquid crystal compound represented by Formula (II), described in WO2017/043438A, is preferably used. The details of a method of producing the λ/4 phase difference plate formed of a liquid crystal compound having reverse wavelength dispersibility can be found in Examples 1 to 10 of WO2017/043438A and Example 1 of JP2016-91022A.

A thickness of the λ/4 phase difference plate is not particularly limited, but is preferably 0.1 μm to 100 μm and more preferably 0.5 μm to 5 μm.

### <Circularly Polarizing Plate>

It is preferable that the circularly polarizing plate is disposed on a side of the reflective layer opposite to an uneven structure with a depth of at least 1 μm or more on the outermost surface.

The decorative film including the circularly polarizing plate can be made to have unique designability where, in a case where the visible side is bright through a film such as a half mirror, the decorative film is visually recognized as a decorative material without the back side seeing therethrough and in a case where the back side is bright, the decorative film is visually recognized as a transparent film.

Examples of the circularly polarizing plate include a plate where a linearly polarizing plate and a λ/4 phase difference plate are laminated. In a configuration of the circularly polarizing plate, the λ/4 phase difference plate and the linearly polarizing plate are disposed in this order from the circularly polarized light reflection layer side. The linearly polarizing plate and the λ/4 phase difference plate are disposed to make a slow axis of the λ/4 phase difference plate and a transmission axis of the linearly polarizing plate match with each other such that, for example, light incident from the linearly polarizing plate side is converted into levorotatory circularly polarized light or dextrorotatory circularly polarized light by the λ/4 phase difference plate.

More specifically, it is preferable that the linearly polarizing plate and the λ/4 phase difference plate are disposed such that an angle between the slow axis of the λ/4 phase difference plate and the transmission axis of the linearly polarizing plate is typically 45°.

In a case where the decorative film includes the circularly polarizing plate, the above-described pressure sensitive adhesive layer may be disposed between the circularly polarizing plate and the circularly polarized light reflection layer.

A thickness of the circularly polarizing plate is not particularly limited, but is preferably 1 μm to 150 μm, more preferably 2 μm to 100 μm, and still more preferably 5 μm to 60 μm.

[Physical properties and the like of decorative sheet] A transmittance of circularly polarized light of the decorative film in a visible range (hereinafter, also referred to as “visibility-corrected circularly polarized light transmittance”) is preferably 20% or more, more preferably 30% or more, still more preferably 40% or more, and still more preferably 50% or more. In a case where the visibility-corrected circularly polarized light transmittance is 30% or more, in a case where the decorative film is applied to a display device, the transmittance during the display ON (turn-on) of the display device is excellent, and the visibility of an image displayed by the display device is improved. The visibility-corrected circularly polarized light transmittance of the decorative film in a visible range is preferably 95% or less, more preferably 75% or less, and still more preferably 65% or less. In a case where the circularly polarized light transmittance is 75% or less, it is possible to achieve both suppression of tint change in a case where the decorative film is observed from an oblique direction, and improvement of image visibility in a case where the decorative film is applied to the display device.

A thickness of the decorative film is not particularly limited, but is preferably 50 μm to 1,500 μm, more preferably 100 μm to 1,000 μm, and still more preferably 150 μm to 500 μm.

### <<Pressure Sensitive Adhesive>>

In a case where the decorative film according to one embodiment of the present disclosure is a decorative film obtained by laminating the reflective layer, the λ/4 phase difference plate, the layer having an uneven structure with a depth of at least 1 μm or more on the outermost surface, and the like, a pressure sensitive adhesive or an adhesive can be used. Examples of the pressure sensitive adhesive include an acrylic pressure sensitive adhesive, a rubber-based pressure sensitive adhesive, and a silicone-based pressure sensitive adhesive. In addition, examples of the pressure sensitive adhesive include acrylic pressure sensitive adhesives, ultraviolet (UV) curable pressure sensitive adhesives, and silicone-based pressure sensitive adhesives described in Chapters 2 of “Characterization evaluation of release paper, release film, and adhesive tape, and control technique thereof”, 2004, Information Mechanism. The acrylic pressure sensitive adhesive in the present disclosure refers to a pressure sensitive adhesive including a polymer (that is, a (meth)acrylic polymer) of a (meth)acrylic monomer. In a case where the resin layer contains a pressure sensitive adhesive, the resin layer may further contain a viscosity imparting agent.

### <<Adhesive>>

Examples of the adhesive include a urethane resin adhesive, a polyester adhesive, an acrylic resin adhesive, an ethylene vinyl acetate resin adhesive, a polyvinyl alcohol adhesive, a polyamide adhesive, and a silicone adhesive. From the viewpoint of higher adhesive force, a urethane resin adhesive or a silicone adhesive is preferable.

### <Base Material>

The decorative film according to one embodiment of the present disclosure preferably includes a base material. The base material may be a support. As the base material, for example, a known base material in the related art as a base material used for molding such as three-dimensional molding and insert molding can be used without particular limitation, and may be appropriately selected according to suitability for molding. In addition, a shape and a material of the base material are not particularly limited, and may be appropriately selected as desired. From the viewpoint of ease of molding and the like, the base material is preferably a resin base material, and more preferably a resin film.

Specific examples of the base material include a resin film including a resin such as polyethylene terephthalate (PET), polyethylene naphthalate (PEN), an acrylic resin, a urethane resin, a urethane-acrylic resin, polycarbonate (PC), an acrylic-polycarbonate resin, triacetyl cellulose (TAC), cycloolefin polymer (COP), and acrylonitrile/butadiene/styrene copolymer resin (ABS resin). Among these, from the viewpoint of moldability and strength, the base material is preferably polyethylene terephthalate (PET), an acrylic resin, polycarbonate, or polypropylene, and more preferably polyethylene terephthalate (PET), an acrylic resin, or polycarbonate. In addition, the base material may be a laminated resin base material having two or more layers. Preferred examples thereof include a laminated film including an acrylic resin layer and a polycarbonate layer.

The base material may contain other additives as necessary. Examples of such additives include lubricants (for example, mineral oil, hydrocarbons, fatty acids, alcohols, fatty acid esters, fatty acid amides, metallic soaps, natural waxes, and silicone), inorganic flame retardants (for example, magnesium hydroxide and aluminum hydroxide), a halogen-based organic flame retardant, a phosphorus-based organic flame retardant, organic or inorganic fillers (for example, metal powder, talc, calcium carbonate, potassium titanate, glass fibers, carbon fibers, and wood powder), an antioxidant, an ultraviolet inhibitor, a dispersant, a coupling agent, a foaming agent, a colorant, and engineering plastics other than the above-described resins. Examples of the engineering plastics include polyolefins, polyesters, polyacetals, polyamides, and polyphenylene ethers.

As the base material, a commercially available product may be used. Examples of the commercially available product include TECHNOLLOY (registered trademark) series (acrylic resin film or acrylic resin/polycarbonate resin laminated film, manufactured by Sumitomo Chemical Co., Ltd.), ABS films (manufactured by Okamoto Industries, Inc.), ABS sheets (manufactured by SEKISUI SEIKEI CO., LTD.), Teflex (registered trademark) series (PET film, manufactured by TEIJIN FILM SOLUTIONS LIMITED), Lumirror (registered trademark) easily moldable type (PET film, manufactured by TORAY INDUSTRIES, INC), and Purethermo (polypropylene film, manufactured by Idemitsu Kosan Co., Ltd.).

A thickness of the base material is determined according to, for example, the application of a molded product to be produced and handleability, and is not particularly limited. The lower limit of the thickness of the base material is preferably 1 μm or more, more preferably 10 μm or more, still more preferably 20 μm or more, and particularly preferably 30 μm or more. The upper limit of the thickness of the base material is preferably 500 μm or less, more preferably 200 μm or less, and particularly preferably 100 μm or less.

### <Other Layers>

The decorative film according to one embodiment of the present disclosure may include other layers in addition to the above-described layers. Examples of the other layers include a self-repairing layer, an antistatic layer, an antifouling layer, an anti-electromagnetic wave layer, and a conductive layer, which are known as a layer for a decorative film. The other layers in the decorative film according to one embodiment of the present disclosure can be formed by known methods. Examples thereof include a method of applying a composition (composition for forming a layer) containing components included in these layers in a layered shape, and drying the composition.

### <<Cover Film>>

For the purpose of preventing stains, and the like, the decorative film according to one embodiment of the present disclosure may include a cover film as an outermost layer on the reflective layer side based on the base material. The cover film is not particularly limited as long as the cover film is formed of a material having flexibility and good peelability, and examples thereof include resin films. Examples of the resin film include a polyethylene film. The cover film is introduced into the decorative film, for example, by attaching the cover film to an object (for example, the reflective layer). The method for attaching the cover film is not particularly limited, and examples thereof include a known attaching method, such as a method of laminating the cover film on the object (for example, the reflective layer).

### <Layer Configuration of Decorative Film>

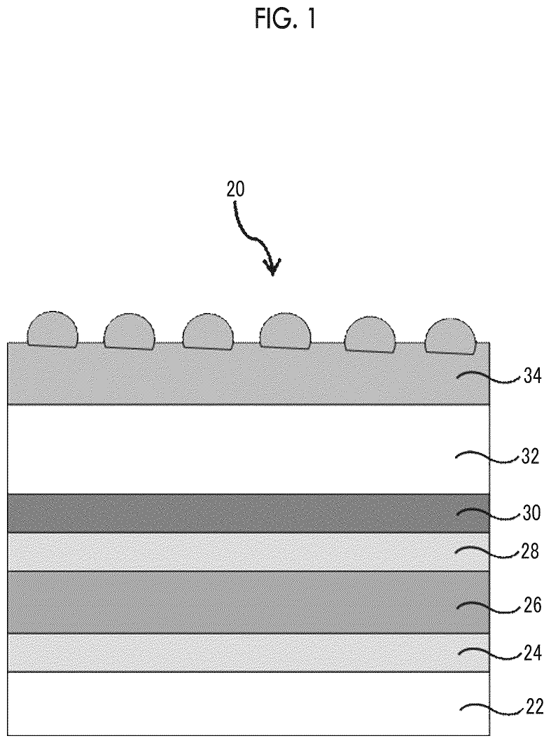

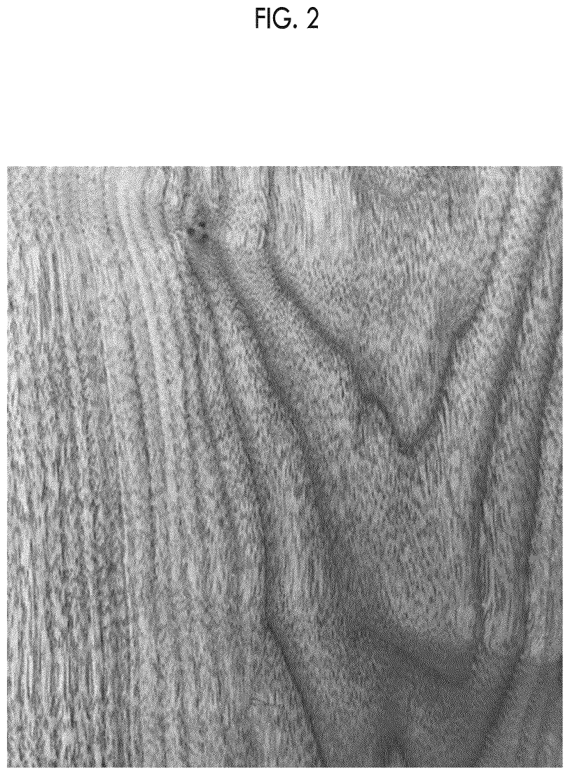

Here, examples of a layer configuration of the decorative film will be described with reference to FIGS. 1 and 2, respectively. However, the layer configuration of the decorative film is not limited to the layer configuration shown in each figure.

FIG. 1 is a schematic cross-sectional view showing an example of layer configuration of the decorative film according to the embodiment of the present disclosure. A decorative film 20 shown in FIG. 1 includes a release film 22, a pressure-sensitive adhesive layer 24 on the release film 22, a circularly polarizing plate 26 on the pressure-sensitive adhesive layer 24, a pressure-sensitive adhesive layer 28 on the circularly polarizing plate 26, a cholesteric liquid crystal layer 30 on the pressure-sensitive adhesive layer 28, a base material 32 on the cholesteric liquid crystal layer 30, and a coating layer 34 formed in a convex shape, on the base material 32.

### <Method for Manufacturing Decorative Film>

A method for manufacturing the decorative film according to one embodiment of the present disclosure is not limited. For example, the decorative film according to one embodiment of the present disclosure can be manufactured by, after laminating the reflective layer and layers other than the reflective layer as necessary on the base material with a pressure sensitive adhesive or the like, forming the convex portion by applying a coating layer containing particles having an average particle diameter of 1 μm or more to the outermost surface. As a method for forming each layer, the above-described method can be used. The decorative film may be manufactured by manufacturing a plurality of laminates including two or more layers in advance, and superimposing the plurality of laminates.

### (Decorative Panel)

The decorative panel according to the embodiment of the present disclosure can be manufactured, for example, by adhering the decorative film and a surface of a member serving as a surface layer portion of the decorative panel. Examples of the member serving as the surface layer portion of the decorative panel include a glass panel, a polycarbonate panel, and an acrylic panel. For example, the above-described adhesive layer can be used for adhering the decorative molded article to the member serving as the surface layer portion of the decorative panel. The decorative film may be used alone as the decorative panel without combining the decorative film with other members.

A shape of the decorative panel is not limited. The shape of the decorative panel may be determined, for example, according to the use. The decorative panel may have, for example, a flat plate. In addition, the decorative panel may have a curved surface.

### <Layer Configuration of Decorative Panel>

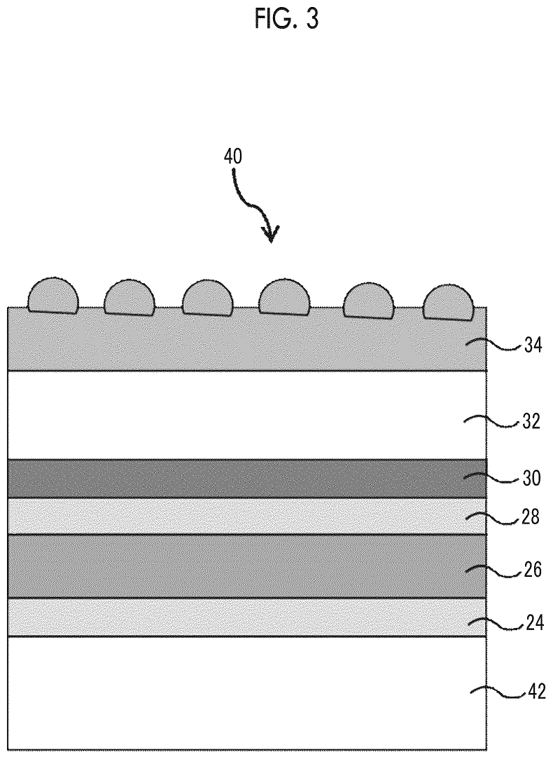

An example of a layer configuration of the decorative panel will be described with reference to FIG. 3. However, the layer configuration of the decorative panel is not limited to the layer configuration shown in the figure.

FIG. 3 is a schematic cross-sectional view showing an example of a layer configuration of the decorative panel according to the embodiment of the present disclosure. A decorative panel 40 shown in FIG. 3 includes a transparent body 42, a pressure-sensitive adhesive layer 24 on the transparent body 42, a circularly polarizing plate 26 on the pressure-sensitive adhesive layer 24, a pressure-sensitive adhesive layer 28 on the circularly polarizing plate 26, a cholesteric liquid crystal layer 30 on the pressure-sensitive adhesive layer 28, a base material 32 on the cholesteric liquid crystal layer 30, and a coating layer 34 formed in a convex shape, on the base material 32.

### <Method for Manufacturing Decorative Panel>

A method for manufacturing the decorative panel according to one embodiment of the present disclosure is preferably a method using the decorative film according to one embodiment of the present disclosure. Examples of the method for manufacturing the decorative panel according to one embodiment of the present disclosure include a process in which, after laminating the reflective layer and layers other than the reflective layer as necessary on the base material with a pressure sensitive adhesive or the like, the convex portion is formed by applying a coating layer containing particles having an average particle diameter of 1 μm or more to the outermost surface, and then a transparent body such as transparent plastic is laminated thereon with a pressure sensitive adhesive or the like. Since the decorative film according to one embodiment of the present disclosure has excellent three-dimensional moldability, the decorative film according to one embodiment of the present disclosure can be suitably used for manufacturing a decorative panel, and for example, it is particularly suitable for manufacturing a decorative panel by at least one molding selected from the group consisting of three-dimensional molding and insert molding. In addition, according to the decorative film according to one embodiment of the present disclosure, it is also possible to obtain a decorative panel by attaching the decorative film according to one embodiment of the present disclosure to a molded article after molding. In a case of using the decorative film according to one embodiment of the present disclosure in a case of producing a decorative panel, it can be applied to molds having more a complicated shape, smaller shape, and the like, which expands the range of applications of the decorative panel. The layer configuration of the decorative panel obtained by using the decorative film reflects the layer configuration of the decorative film. In other words, the decorative panel obtained by using the decorative film includes each layer included in the decorative film.

In addition, suitable examples of the molding include three-dimensional molding. Suitable examples of the three-dimensional molding include heat molding, vacuum molding, pressure molding, and vacuum pressure molding. A method of performing the vacuum molding is not particularly limited, but is preferably a method of performing three-dimensional molding in a heated state under vacuum. The vacuum means a state in which an inside of a chamber is reduced to a degree of vacuum of 100 Pa or less. It is sufficient that the temperature in a case of performing the three-dimensional molding is appropriately set depending on the used base material for molding, but the temperature is preferably in a temperature range of 60° C. or higher, more preferably in a temperature range of 80° C. or higher, and still more preferably in a temperature range of 100° C. or higher. The upper limit of the temperature in a case of performing the three-dimensional molding is preferably 200° C. The temperature in a case of performing the three-dimensional molding means a temperature of the base material for molding supplied for the three-dimensional molding, and is measured by attaching a thermocouple to the surface of the base material for molding.

The vacuum molding can be performed using a vacuum molding technique widely known in the molding field, and for example, the vacuum molding may be performed using Formech 508FS manufactured by NIHON SEIZUKI KOGYO CO., LTD.

### <Use>

The use of the decorative panel obtained as described above is not particularly limited, and the decorative panel can be used for various articles. Particularly suitable examples of the use of the decorative molded article include interiors and exteriors of display devices (for example, wearable devices and smartphones), interiors and exteriors of automobiles, interiors and exteriors of electric appliances, and packaging containers.

The decorative panel can be manufactured, for example, by adhering a surface of the decorative molded article on the reflective layer side to a surface of a member serving as a surface layer portion of the decorative panel. Examples of the member serving as the surface layer portion of the decorative panel include a glass panel. For example, the above-described adhesive layer can be used for adhering the decorative molded article to the member serving as the surface layer portion of the decorative panel. The decorative molded article may be used alone as the decorative panel without combining the decorative molded article with other members.

### [Display Device]

The display device (image display apparatus) according to the embodiment of the present disclosure includes a display element and the above-described decorative film disposed on the display element. The display element used for the display device according to the embodiment of the present disclosure is not particularly limited, and examples thereof include a liquid crystal cell, an organic electroluminescent (organic EL) display panel, and a plasma display panel.

Among these, a liquid crystal cell or an organic EL display panel is preferable, and an organic EL display panel is more preferable. That is, as the display device according to the embodiment of the present disclosure, a liquid crystal display device obtained by using a liquid crystal cell as a display element or an organic EL display device obtained by using an organic EL display panel as a display element is preferable. Emitted light of the display element is preferably linearly polarized light.

The display device (image display apparatus) according to the embodiment of the present disclosure is a liquid crystal display device or an organic electroluminescent display device.

In a case where the display device includes the decorative sheet and an image is not displayed by the display element, the pattern of the decorative film itself is visually recognized. Here, since the display device according to the embodiment of the present invention includes the above-described decorative film, in a case where an image is not displayed by the display element, the pattern of the decorative film can be visually recognized favorably from any direction, and a tint change depending on directions is also small.

Examples of a preferred aspect of the display device according to the embodiment of the present disclosure include an automobile interior material.

### [Liquid Crystal Display Device]

The liquid crystal cell used for the liquid crystal display device is preferably a vertical alignment (VA) mode, an optically compensated bend (OCB) mode, an in-plane-switching (IPS) mode, or a twisted nematic (TN) mode, but the liquid crystal cell is not limited thereto.

In the liquid crystal cell in the TN mode, during non-voltage application, rod-like liquid crystal molecules (rod-like liquid crystal compound) are substantially horizontally aligned and further twisted and aligned at 60° to 120°. The liquid crystal cell in a TN mode is most frequently used as a color TFT liquid crystal display device and is described in a plurality of documents. In the liquid crystal cell in a VA mode, rod-like liquid crystalline molecules are substantially vertically aligned at the time of no voltage application. Examples of the liquid crystal cell in the VA mode includes (1) a liquid crystal cell in the VA mode in a narrow sense where rod-like liquid crystal molecules are substantially vertically aligned during non-voltage application and are substantially horizontally aligned during voltage application (described in JP1990-176625A (JP-H2-176625A)), (2) a liquid crystal cell (in a multi-domain vertical alignment (MVA) mode) where multiple domains are provided in the VA mode (described in SID97, Digest of tech. Papers (proceedings), 28 (1997) 845) to expand the viewing angle, (3) a liquid crystal cell in an axially symmetric aligned microcell (n-ASM) mode in which rod-like liquid crystal molecules are substantially vertically aligned during non-voltage application and are twisted and aligned in multi-domains during voltage application (described in proceedings of Japanese Liquid Crystal Conference, pp. 58 to 59 (1998)), and (4) a liquid crystal cell in a SURVIVAL mode (presented at liquid crystal cell (LCD) International 98). The liquid crystal cell may be any one of a patterned vertical alignment (PVA) type, an optical alignment type, or a polymer-sustained alignment (PSA). These modes are described in detail in JP2006-215326A and JP2008-538819A.

In the liquid crystal cell in an IPS mode, rod-like liquid crystalline molecules are aligned substantially parallel to the substrate, and the liquid crystalline molecules respond planarly through application of an electric field parallel to the substrate surface. In the IPS mode, black display is carried out in a state where no electric field is applied, and absorption axes of a pair of upper and lower polarizing plates are orthogonal to each other. A method of reducing leakage light during black display in an oblique direction and improving the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

Preferable examples of the organic EL display device which is an example of the display device according to the embodiment of the present disclosure include an aspect where the decorative layer including the above-described decorative sheet, the circularly polarized light reflection layer including the above-described decorative sheet, and an organic EL display panel are disposed in this order from the visible side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present disclosure will be more specifically described with reference to Examples. The scope of the present disclosure is not limited to the specific examples shown below.

### Example 1

### <Preparation of Support>

As a support, COSMOSHINE A4100 (PET film, thickness: 75 μm, manufactured by Toyobo Co., Ltd.) was prepared.

### <Formation of Alignment Layer 1>

A coating liquid 1 for forming an alignment layer was applied onto the above-described support using a wire bar coater. Thereafter, the applied coating liquid 1 for forming an alignment layer was dried at 100° C. for 120 seconds to produce an alignment layer 1 having a layer thickness of 0.5 μm.

### [Composition of Coating Liquid 1 for Forming Alignment Layer]

Modified polyvinyl alcohol shown below: 28 parts by mass
Citric acid ester (AS3, manufactured by SANKYO CHEMICAL Co., Ltd.): 1.2 parts by mass
Photopolymerization initiator (IRGACURE 2959, manufactured by BASF): 0.84 parts by mass
Glutaraldehyde: 2.8 parts by mass
Water: 699 parts by mass
Methanol: 226 parts by mass
Modified polyvinyl alcohol (the following compounds; the numbers at the lower right of each constitutional unit represent the molar ratio)

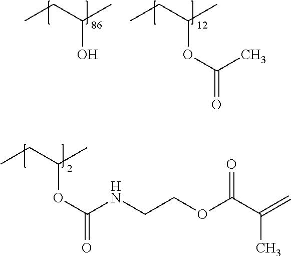

### <Formation of Cholesteric Liquid Crystal Layer (Reflective Layer) 1>

Components included in the coating liquid 1 for forming a cholesteric liquid crystal layer, which are shown below, were stirred and dissolved in a container kept at a temperature of 25° C. to prepare a coating liquid 1 for forming a cholesteric liquid crystal layer (liquid crystal composition 1).

### [Composition of Coating Liquid 1 for Forming Cholesteric Liquid Crystal Layer]

Methyl ethyl ketone: 150.6 parts by mass
Liquid crystal compound 1 (rod-like liquid crystal compound): 92 parts by mass
Photopolymerization initiator A (IRGACURE 907, manufactured by BASF): 0.50 parts by mass
Chiral agent A: 4.00 parts by mass
Chiral agent B: 4.00 parts by mass
Surfactant F1 described below: 0.027 parts by mass

Liquid crystal compound 1 (rod-like liquid crystal compound): compound shown below

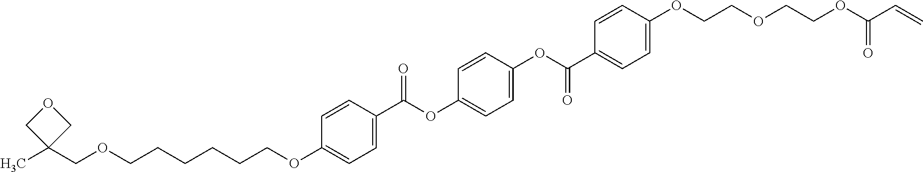 [SMILES: C=CC(=O)OCCOCCOc1ccc(C(=O)Oc2ccc(OC(=O)c3ccc(OCCCCCCOCC4(C)COC4)cc3)cc2)cc1]

Chiral agent A (bifunctional): compound shown below

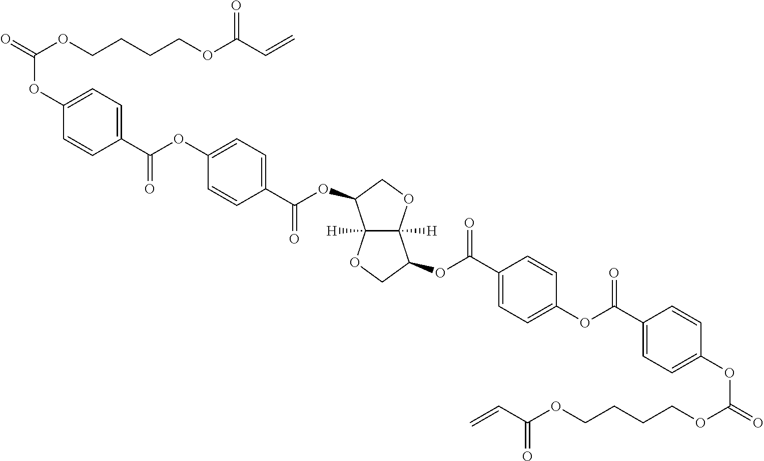 [SMILES: C=CC(=O)OCCCCOC(=O)Oc1ccc(C(=O)Oc2ccc(C(=O)O[C@H]3CO[C@@H]4[C@H]3OC[C@@H]4OC(=O)c3ccc(OC(=O)c4ccc(OC(=O)OCCCCOC(=O)C=C)cc4)cc3)cc2)cc1]

Chiral agent B (non-functional): compound shown below; in the following compound, Bu represents an n-butyl group.

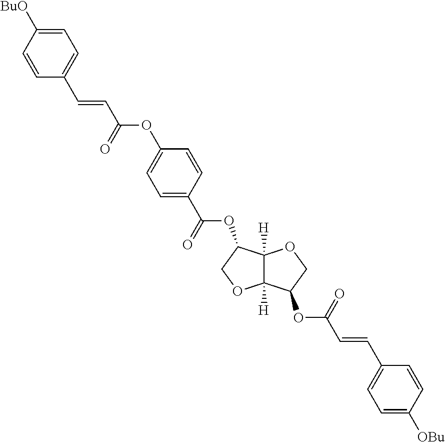

Surfactant F1: compound shown below

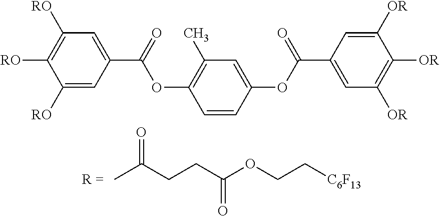

The coating liquid 1 for forming a cholesteric liquid crystal layer prepared above was applied onto the rubbing-treated surface of the alignment layer 1 with a wire bar coater, and dried at 85° C. for 120 seconds. Thereafter, an upper surface of the cholesteric liquid crystal layer in the formed laminate was irradiated with light from a metal halide lamp in a low oxygen atmosphere (100 ppm or less) at 25° C. and an irradiation amount of 60 mJ through an exposure mask for forming a grain pattern, as shown in FIG. 2. Furthermore, the upper surface thereof was irradiated with light from a metal halide lamp at 120° C. and an irradiation amount of 100 mJ through an optical filter SH0350 (manufactured by Asahi Spectra Co., Ltd.), and was retained at 120° C. for 2 minutes. Subsequently, the upper surface thereof was irradiated with light from a metal halide lamp in a low oxygen atmosphere (100 ppm or less) at 120° C. and an irradiation amount of 300 mJ As a result, a cholesteric liquid crystal layer 1 was cured.

### <Formation of Layer 1 Having Convex Shape>

A polymethyl methacrylate (PMMA) film (TECHNOLLOY S001, manufactured by Sumika Acryl Co., Ltd.) having a thickness of 125 μm was prepared. In addition, components contained in a coating liquid 1 for forming a cholesteric layer having a convex shape were stirred and dissolved in a container kept at 25° C. to prepare a coating liquid 1 for forming the layer having a convex shape (coating liquid 1 of a layer forming a convex shape).

### [Composition of Coating Liquid 1 for Forming Layer Having Convex Structure]

Methyl ethyl ketone: 80 parts by mass
Acrylic particles (Micropearl BK515, size: 15 μm, black, manufactured by SEKISUI CHEMICAL CO., LTD.): 0.10 parts by mass
Acrylic particles (Micropearl BK506, size: 6 μm, black, manufactured by SEKISUI CHEMICAL CO., LTD.): 0.50 parts by mass
Photocurable acrylic polymer (Acrit 8KX-077, manufactured by Taisei Fine Chemical Co., Ltd.): 20 parts by mass
Photopolymerization initiator (IRGACURE 2959, manufactured by BASF): 0.1 parts by mass
Surfactant (MEGAFACE F553, manufactured by DIC CORPORATION): 0.01 parts by mass

The coating liquid 1 for forming a layer having a convex structure prepared above was applied onto a surface of the PMMA film having a thickness of 125 μm using a wire bar coater so that a thickness of a binder was 7 μm, and then dried at 85° C. for 120 seconds. Thereafter, an upper surface of the layer having a convex structure in the formed laminate was irradiated with light from a metal halide lamp in a low oxygen atmosphere (100 ppm or less) at 25° C. and an irradiation amount of 500 mJ to cure the coating liquid 1 for forming a layer having a convex structure.

In a case where a surface state of the obtained layer having a convex structure was analyzed using a laser microscope (manufactured by KEYENCE CORPORATION), 16 sites where a height of the convex structure was 1 μm or more were observed within 200 μm².

### <Production of Decorative Film>

The reflective layer 1 produced above was bonded to a surface of the PMMA film, on which the layer having a convex structure was not formed, using a pressure sensitive adhesive (manufactured by Soken Chemical & Engineering Co., Ltd., SK2057). An amount of the pressure sensitive adhesive attached was adjusted such that a thickness of a layer formed of the pressure sensitive adhesive (pressure sensitive adhesive layer) was 25 μm.

Further, the PET film was peeled off. Furthermore, a circularly polarizing plate 1 was separately produced in the same manner as a circularly polarizing plate 21 described in JP6276393B, and an optically-anisotropic layer of the circularly polarizing plate 1 and the circularly polarizing plate of the decorative sheet were bonded together using a pressure sensitive adhesive (manufactured by Soken Chemical & Engineering Co., Ltd., SK2057). Thereafter, a pressure sensitive adhesive (manufactured by Soken Chemical & Engineering Co., Ltd., SK2057) was bonded to a surface of the circularly polarizing plate opposite to the reflective layer, and a silicone-based release film (LT-H, manufactured by LINTEC Corporation) was bonded to the pressure sensitive adhesive to produce a decorative film.

An amount of the pressure sensitive adhesive attached was adjusted such that a thickness of a layer formed of the pressure sensitive adhesive (pressure sensitive adhesive layer) was 25 μm. Here, an angle between the optically-anisotropic layer of the circularly polarizing plate 1 and the absorption axis of the polarizer was any one of 45° clockwise or 45° counterclockwise, the circularly polarizing plate 1 was disposed on the circularly polarized light reflection layer side of the decorative sheet, and an axis relationship between the optically-anisotropic layer of the circularly polarizing plate 1 and the absorption axis of the polarizer was set such that a scenery on the depth side of the decorative sheet was able to be seen from the circularly polarizing plate.

### <Performance Evaluation>

### —Visibility of Decorative Film—

The decorative film 1 was bonded to a display (11-inch iPad Pro (registered trademark) third generation, manufactured by Apple Inc. using a pressure sensitive adhesive (manufactured by Soken Chemical & Engineering Co., Ltd., SK2057), and in a state of being irradiated with an LED light source (LA-HDF108AA, manufactured by HAYASHI-REPIC CO., LTD.) from a distance of 1 m at an angle of 45° from the surface of the decorative film, visibility of the decorative film with the display turned off was confirmed from a position 1 m away from an opposite side of the light source at an angle of 45°. As an evaluation result, C is preferable, B is more preferable, and A is particularly preferable.

### <<Evaluation Standard>>

A: decorative film was clearly visible from any angle.

B: visibility of the decorative film was slightly low, but the decoration was able to be recognized.

C: visibility of the decorative film was low, but the decoration was able to be recognized.

D: visibility of the decorative film was low, and there was a region where the light source was reflected and the decoration was not able to be recognized.

—Light Source Visibility in Case where Back Surface Display was Turned On—

The decorative film 1 was bonded to a display device (11-inch iPad Pro (registered trademark) third generation, manufactured by Apple Inc. using a pressure sensitive adhesive (manufactured by Soken Chemical & Engineering Co., Ltd., SK2057), and visibility of characters was evaluated by displaying characters with a font size of 12 while the display was turned on. The observation was carried out at a position 1 m away from the front side of the decorative film. As an evaluation result, Cis preferable, B is more preferable, and A is particularly preferable.

### <<Evaluation Standard>>

A: characters of the display were clearly confirmed.

B: characters of the display were slightly blurred, but the content of the display was clearly confirmed.

C: characters of the display were blurred, but the content of the display could be confirmed.

D: characters of the display were blurred, and the content of the display was unclear.

### —Evaluation of Tactile Sensation—

The surface of the obtained decorative film was rubbed back and forth 3 times with a finger to evaluate tactile sensation. As an evaluation result, C is preferable, B is more preferable, and A is particularly preferable.

### <<Evaluation Standard>>

A: surface was silky and a smooth tactile sensation was obtained.

B: surface was slightly rough or sticky, but a relatively smooth tactile sensation was obtained.

C: surface was rough or sticky, but a smoothness difference was within an acceptable range.

D: surface was rough or sticky, and the tactile sensation was not smooth.

### Examples 2 to 6

A decorative film was produced in the same manner as in Example 1, except that, with regard to the reflective layer, the film thickness of the reflective layer was changed so that the reflectivity of the reflective layer described in Table 1 was obtained. Using the obtained decorative film, the same performance evaluations as the performance evaluations of Example 1 were performed. The evaluation results are shown in Table 1.

### Example 7

A decorative film was produced in the same manner as in Example 1, except that, with regard to the reflective layer, the film thickness of the reflective layer was changed so that the reflectivity of the reflective layer described in Table 1 was obtained. Using the obtained decorative film, the same performance evaluations as the performance evaluations of Example 1 were performed. The evaluation results are shown in Table 1.

### Example 8

A decorative film was produced in the same manner as in Example 1, except that the acrylic particles (Micropearl BK515, size: 15 μm) were changed to black magnetic polyethylene particles (BKPMS-1.2.20-27 μm, black, manufactured by Cospheric LLC). The evaluation results are shown in Table 1.

### Example 9

A decorative film was produced in the same manner as in Example 1, except that the acrylic particles (Micropearl BK515, size: 15 μm) were changed to black magnetic polyethylene particles (BKPM- 1.2.53-63 μm, black, manufactured by Cospheric LLC), and the addition amount of the photocurable acrylic polymer was changed to 40 parts by mass. The evaluation results are shown in Table 1.

### Example 10

A decorative film was produced in the same manner as in Example 1, except that the acrylic particles (Micropearl BK515, size: 15 μm) were changed to black magnetic polyethylene particles (BKPM-1.2.106-125 μm, black, manufactured by Cospheric LLC), and the addition amount of the photocurable acrylic polymer was changed to 60 parts by mass. The evaluation results are shown in Table 1.

### Example 11

A decorative film was produced in the same manner as in Example 1, except that the acrylic particles (Micropearl BK515, size: 15 μm) were changed to acrylic particles (Micropearl BK512, size: 12 μm, black, manufactured by SEKISUI CHEMICAL CO., LTD.). The evaluation results are shown in Table 1.

### Example 12

A decorative film was produced in the same manner as in Example 1, except that the acrylic particles (Micropearl BK515, size: 15 μm) were changed to acrylic particles (Micropearl BK510, size: 10 μm, black, manufactured by SEKISUI CHEMICAL CO., LTD.). The evaluation results are shown in Table 1.

### Example 13

A decorative film was produced in the same manner as in Example 1, except that the acrylic particles (Micropearl BK515, size: 15 μm) were removed, and the addition amount of the acrylic particles (Micropearl BK506, size: 6 μm) was changed to 0.60 parts by mass. The evaluation results are shown in Table 1.

### Example 14

A decorative film was produced in the same manner as in Example 1, except that the addition amount of the acrylic particles (Micropearl BK515, size: 15 μm) was changed to 0.05 parts by mass. The evaluation results are shown in Table 2.

### Example 15

A decorative film was produced in the same manner as in Example 1, except that the addition amount of the acrylic particles (Micropearl BK515, size: 15 μm) was changed to 0.025 parts by mass. The evaluation results are shown in Table 2.

### Example 16

A decorative film was produced in the same manner as in Example 1, except that the addition amount of the acrylic particles (Micropearl BK515, size: 15 μm) was changed to 0.12 parts by mass. The evaluation results are shown in Table 2.

### Example 17

A decorative film was produced in the same manner as in Example 1, except that the addition amount of the acrylic particles (Micropearl BK515, size: 15 μm) was changed to 0.50 parts by mass, and the addition amount of the acrylic particles (Micropearl BK506, size: 6 μm) was changed to 2.5 parts by mass. The evaluation results are shown in Table 2.

### Example 18

A decorative film was produced in the same manner as in Example 1, except that the addition amount of the acrylic particles (Micropearl BK515, size: 15 μm) was changed to 0.563 parts by mass. The evaluation results are shown in Table 2.

### Example 19

A decorative film was produced in the same manner as in Example 1, except that the addition amount of the acrylic particles (Micropearl BK515, size: 15 μm) was changed to 1.19 parts by mass. The evaluation results are shown in Table 2.

### Example 20

A decorative film was produced in the same manner as in Example 1, except that the addition amount of the acrylic particles (Micropearl BK515, size: 15 μm) was changed to 1.86 parts by mass. The evaluation results are shown in Table 2.

### Example 21

A decorative film was produced in the same manner as in Example 1, except that the acrylic particles (Micropearl BK515, size: 15 μm, black) were changed to acrylic particles (MX1500H, size: 15 μm, black, manufactured by Soken Chemical & Engineering Co., Ltd., transparent color), and the acrylic particles (Micropearl BK506, size: 6 μm) were changed to acrylic particles (MX500, size: 5 μm, black, manufactured by Soken Chemical & Engineering Co., Ltd., transparent color). The evaluation results are shown in Table 2.

### Example 22

A decorative film was produced in the same manner as in Example 1, except that, with regard to the reflective layer, the liquid crystal compound 1 of the reflective layer 1 was changed to a liquid crystal compound 2 to obtain a reflective layer 2. Using the obtained decorative film, the same performance evaluations as the performance evaluations of Example 1 were performed. The evaluation results are shown in Table 3.

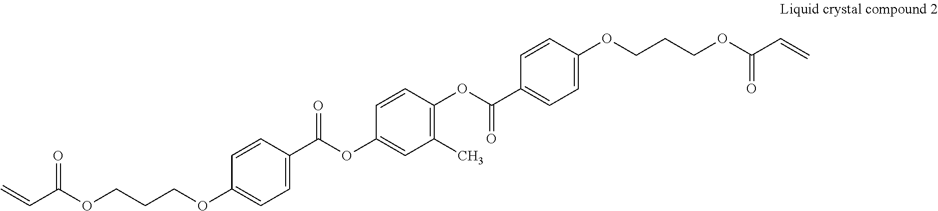 [SMILES: C=CC(=O)OCCCOc1ccc(C(=O)Oc2ccc(OC(=O)c3ccc(OCCCOC(=O)C=C)cc3)c(C)c2)cc1]

### Example 23

A decorative film was produced in the same manner as in Example 1, except that, with regard to the reflective layer, the liquid crystal compound 1 of the reflective layer 1 was changed to a liquid crystal compound 3 to obtain a reflective layer 3. Using the obtained decorative film, the same performance evaluations as the performance evaluations of Example 1 were performed. The evaluation results are shown in Table 3.

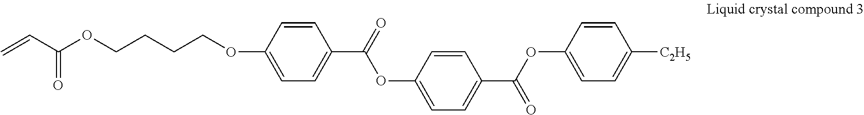 [SMILES: C=CC(=O)OCCCCOc1ccc(C(=O)Oc2ccc(C(=O)Oc3ccc(CC)cc3)cc2)cc1]

### Example 24

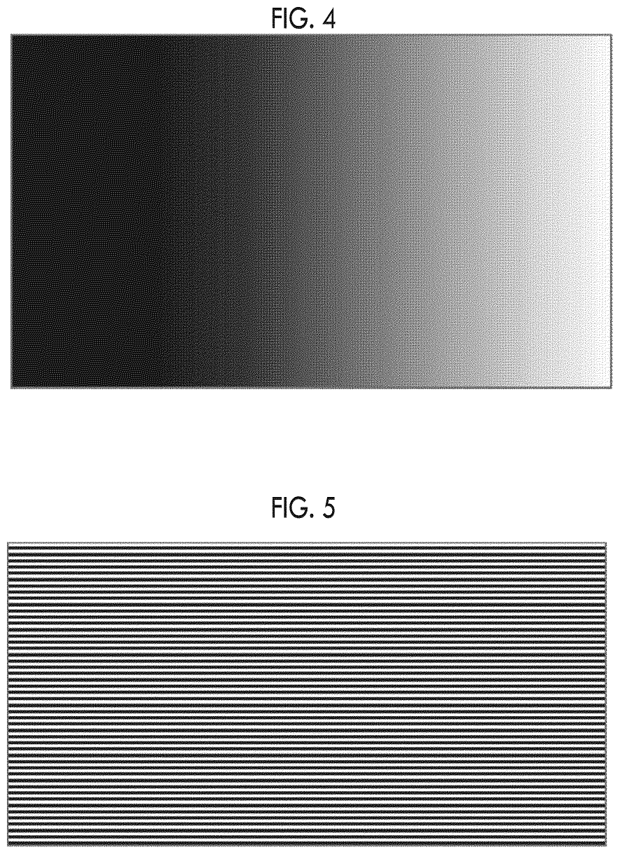

A decorative film was produced in the same manner as in Example 1, except that, in the formation of the reflective layer, the exposure mask used was changed from the grain pattern as shown in FIG. 2 to a gradation pattern as shown in FIG. 4. Using the obtained decorative film, the same performance evaluations as the performance evaluations of Example 1 were performed. The evaluation results are shown in Table 3.

### Example 25

A decorative film was produced in the same manner as in Example 1, except that, in the formation of the reflective layer, the exposure mask used was changed from the grain pattern as shown in FIG. 2 to a stripe pattern (line width/pitch: 2 mm/2 mm) as shown in FIG. 5. Using the obtained decorative film, the same performance evaluations as the performance evaluations of Example 1 were performed. The evaluation results are shown in Table 3.

### Examples 26 to 29

A decorative film was produced in the same manner as in Example 1, except that, in the formation of the layer having a convex structure, the amount of binder applied was changed so that the height of the convex structure shown in Table 3 was obtained. Using the obtained decorative film, the same performance evaluations as the performance evaluations of Example 1 were performed. The evaluation results are shown in Table 3.

### Comparative Example 1

A decorative film was produced in the same manner as in Example 1, except that, with regard to the reflective layer, the film thickness of the reflective layer was changed so that the reflectivity was 3%. The evaluation results are shown in Table 2.

### Comparative Example 2

A decorative film was produced in the same manner as in Example 1, except that the layer having a convex structure was not adopted. The evaluation results are shown in Table 2.

TABLE 1

| | | | Example | Example | Example | Example | Example | Example | Example |
|---|---|---|---|---|---|---|---|---|---|
| | | | 1 | 2 | 3 | 4 | 5 | 6 | 7 |
| Reflective | Type of reflective | | Reflective | Reflective | Reflective | Reffective | Reflective | Reflective | Reflective |
| layer | layer | | layer 1 | layer 1 | layer 1 | layer 1 | layer 1 | layer 1 | layer 1 |
| | Region having | % | 20 | 10 | 5 | 30 | 40 | 45 | 20 |
| | reflectivity of at | | | | | | | | |
| | least 5% or more | | | | | | | | |
| | Thickness | μm | 2.5 | 1.3 | 0.7 | 3.2 | 3.7 | 5.0 | 2.5 |
| | Design | | Grain | Grain | Grain | Grain | Grain | Grain | Grain |
| Layer | Type of layer having | | Layer | Layer | Layer | Layer | Layer | Layer | Layer |
| having | convex structure | | having | having | having | having | having | having | having |
| convex | | | convex | convex | convex | convex | convex | convex | convex |
| structure | | | shape 1 | shape 1 | shape 1 | shape 1 | shape 1 | shape 1 | shape 2 |
| | Height of at least 1 | μm | 8 | 8 | 8 | 8 | 8 | 8 | 15 |
| | μm or more on | | | | | | | | |
| | outermost surface | | | | | | | | |
| | Observation of | [sites/200 | 16 | 16 | 16 | 16 | 16 | 16 | 16 |
| | surface state | μm²] | | | | | | | |
| | Coloring of convex | | Y | Y | Y | Y | Y | Y | Y |
| | structure | | Black | Black | Black | Black | Black | Black | Black |
| | | | acrylic | acrylic | acrylic | acrylic | acrylic | acrylic | acrylic |
| | | | particles | particles | particles | particles | particles | particles | particles |

| | | | | | | | | |
|---|---|---|---|---|---|---|---|---|
| Evaluation | Visibility of decorative film | A | A | C | A | A | B | A |
| result | Light source visibility in case where | A | A | A | A | B | C | A |
| | back surface display was turned on | | | | | | | |
| | Evaluation of tactile sensation | A | A | A | A | A | A | A |

| | | | Example | Example | Example | Example | Exampbe | Example |
|---|---|---|---|---|---|---|---|---|
| | | | 8 | 9 | 10 | 11 | 12 | 13 |
| Reflective | Type of reflective | | Reflective | Reflective | Reflective | Reflective | Reflective | Reflective |
| layer | layer | | layer 1 | layer 1 | layer 1 | layer 1 | layer 1 | layer 1 |
| | Region having | % | 20 | 20 | 20 | 20 | 20 | 20 |
| | reflectivity of at | | | | | | | |
| | least 5% or more | | | | | | | |
| | Thickness | μm | 2.5 | 2.5 | 2.5 | 2.5 | 2.5 | 2.5 |
| | Design | | Grain | Grain | Grain | Grain | Gram | Grain |
| Layer | Type of layer having | | Layer | Layer | Layer | Layer | Layer | Layer |
| having | convex structure | | having | having | having | having | having | having |
| convex | | | convex | convex | convex | convex | convex | convex |
| structure | | | shape 3 | shape 4 | shape 5 | shape 6 | shape 7 | shape 8 |
| | Height of at least 1 | μm | 30 | 50 | 100 | 5 | 3 | 1 |
| | μm or more on | | | | | | | |
| | outermost surface | | | | | | | |
| | Observation of | [sites/200 | 16 | 16 | 16 | 16 | 16 | 16 |
| | surface state | μm²] | | | | | | |
| | Coloring of convex | | Y | Y | Y | Y | Y | Y |
| | structure | | Black | Black | Black | Black | Black | Black |
| | | | acrylic | acrylic | acrylic | acrylic | acrylic | acrylic |
| | | | particles | particles | particles | particles | particles | particles |

| | | | | | | | |
|---|---|---|---|---|---|---|---|
| Evaluation | Visibility of decorative film | A | A | B | A | B | C |
| result | Light source visibility in case where | A | A | B | A | B | B |
| | back surface display was turned on | | | | | | |
| | Evaluation of tactile sensation | A | B | C | A | A | C |

TABLE 2

| | | | Example 14 | Example 15 | Example 16 | Example 17 | Example 18 |
|---|---|---|---|---|---|---|---|
| Reflective | Type of reflective | | Reflective | Reflective | Reflective | Reflective | Reflective |
| layer | layer | | layer 1 | layer 1 | layer 1 | layer 1 | layer 1 |
| | Region having | % | 20 | 20 | 20 | 20 | 20 |
| | reflectivity of at | | | | | | |
| | least 5% or more | | | | | | |
| | Thickness | μm | 2.5 | 2.5 | 2.5 | 2.5 | 2.5 |
| | Design | | Grain | Grain | Grain | Grain | Grain |
| Layer having | Type of layer having | | Layer having | Layer having | Layer having | Layer having | Layer having |
| convex | convex structure | | convex | convex | convex | convex | convex |
| structure | | | shape 9 | shape 10 | shape 11 | shape 11 | shape 12 |
| | Height of at least 1 μm | μm | 8 | 8 | 8 | 8 | 8 |
| | or more on outermost | | | | | | |
| | surface | | | | | | |
| | Observation of surface | [sites/200 | 8 | 4 | 10 | 80 | 90 |
| | state | μm²] | | | | | |
| | Coloring of convex | | Y | Y | Y | Y | Y |
| | structure | | Black acrylic | Black acrylic | Black acrylic | Black acrylic | Black acrylic |
| | | | particles | particles | particles | particles | particles |
| Evaluation | Visibility of decorative film | | A | A | A | A | A |
| result | Light source visibility in case where | | A | A | A | A | B |
| | back surface display was turned on | | | | | | |
| | Evaluation of tactile sensation | | B | C | A | A | A |
| | | | | | | Comparative | Comparative |
| | | | Example 19 | Example 20 | Example 21 | Example 1 | Example 2 |
| Reflective | Type of reflective | | Reflective | Reflective | Reflective | Reflective | Reflective |
| layer | layer | | layer 1 | layer 1 | layer 1 | layer 1 | layer 1 |
| | Region having | % | 20 | 20 | 20 | 3 | 20 |
| | reflectivity of at | | | | | | |
| | least 5% or more | | | | | | |
| | Thickness | μm | 2.5 | 2.5 | 2.5 | 0.4 | 2.5 |
| | Design | | Grain | Grain | Grain | Grain | Grain |
| Layer having | Type of layer having | | Layer having | Layer having | Layer having | Layer having | None |
| convex | convex structure | | convex | convex | convex | convex | |
| structure | | | shape 13 | shape 14 | shape 15 | shape 1 | |
| | Height of at least 1 μm | μm | 8 | 8 | 8 | 8 | |
| | or more on outermost | | | | | | |
| | surface | | | | | | |
| | Observation of surface | [sites/200 | 190 | 300 | 16 | 16 | |
| | state | μm²] | | | | | |
| | Coloring of convex | | Y | Y | N | Y | |
| | structure | | Black acrylic | Black acrylic | | Black acrylic | |
| | | | particles | particles | | particles | |

| | | | | | | |
|---|---|---|---|---|---|---|
| Evaluation | Visibility of decorative film | B | C | A | D | D |
| result | Light source visibility in case where | C | C | B | A | A |
| | back surface display was turned on | | | | | |
| | Evaluation of tactile sensation | B | C | A | A | D |

TABLE 3

| | | | Example 22 | Example 23 | Example 24 | Example 25 |
|---|---|---|---|---|---|---|
| Reflective layer | Type of reflective layer | | Reflective | Reflective | Reflective | Reflective |
| | | | layer 2 | layer 3 | layer 1 | layer 1 |
| | Region having reflectivity of at | % | 20 | 20 | 20 | 20 |
| | least 5% or more | | | | | |
| | Thickness | μm | 2.5 | 2.5 | 2.5 | 2.5 |
| | Design | | Grain | Grain | Gradation | Stripe |
| Layer having | Type of layer having convex structure | | Layer having | Layer having | Layer having | Layer having |
| convex structure | | | convex shape 1 | convex shape 1 | convex shape 1 | convex shape 1 |
| | Height of at least 1 μm or more | μm | 8 | 8 | 8 | 8 |
| | on outermost surface | | | | | |
| | Observation of surface state | [sites/200 | 16 | 16 | 16 | 16 |
| | | μm²] | | | | |
| | Coloring of convex structure | | Y | Y | Y | Y |
| | | | Black acrylic | Black acrylic | Black acrylic | Black acrylic |
| | | | particles | particles | particles | particles |
| Evaluation result | Visibility of decorative film | | A | A | A | A |
| | Light source visibility in case where back | | A | A | A | A |
| | surface display was turned on | | | | | |
| | Evaluation of tactile sensation | | A | A | A | A |
| | | | Example 26 | Example 27 | Example 28 | Example 29 |
| Reflective layer | Type of reflective layer | | Reflective | Reflective | Reflective | Reflective |
| | | | layer 1 | layer 1 | layer 1 | layer 1 |
| | Region having reflectivity of at | % | 20 | 20 | 20 | 20 |
| | least 5% or more | | | | | |
| | Thickness | μm | 2.5 | 2.5 | 2.5 | 2.5 |
| | Design | | Grain | Grain | Grain | Grain |
| Layer having | Type of layer having convex structure | | Layer having | Layer having | Layer having | Layer having |
| convex structure | | | convex shape 1 | convex shape 1 | convex shape 1 | convex shape 1 |
| | Height of at least 1 μm or more | μm | 1 | 4 | 12 | 15 |
| | on outermost surface | | | | | |
| | Observation of surface state | [sites/200 | 16 | 16 | 16 | 16 |
| | | μm²] | | | | |
| | Coloring of convex structure | | Y | Y | Y | Y |
| | | | Black acrylic | Black acrylic | Black acrylic | Black acrylic |
| | | | particles | particles | particles | particles |

| | | | | | |
|---|---|---|---|---|---|
| Evaluation result | Visibility of decorative film | A | A | B | B |
| | Light source visibility in case where back | A | C | B | C |
| | surface display was turned on | | | | |
| | Evaluation of tactile sensation | C | A | A | A |

From the results shown in Tables 1 to 3, in Examples 1 to 29, a decorative film having excellent visibility was obtained. In addition, from the results shown in Tables 1 to 3, in Examples 1 to 29, a decorative film which was also excellent in light source visibility in a case where the back surface display was turned on and in providing a tactile sensation was obtained. On the other hand, in Comparative Example 1 in which the reflective layer has a reflectivity of 5% or less, the visibility of the decorative film was low, and in Comparative Example 2 which did not have the convex shape, the evaluation of the tactile sensation was low.

The disclosure of Japanese Patent Application No. 2021-131978 filed on Aug. 13, 2021 and the disclosure of Japanese Patent Application No. 2022-113386 filed on Jul. 14, 2022 are incorporated in the present specification by reference.

All documents, patent applications, and technical standards described in the present specification are herein incorporated by reference to the same extent that each individual document, patent application, or technical standard was specifically and individually indicated to be incorporated by reference.

### EXPLANATION OF REFERENCES

20: decorative film
22: release film
24: pressure-sensitive adhesive layer
26: circularly polarizing plate
28: cholesteric liquid crystal layer
30: pressure-sensitive adhesive layer
32: base material
34: layer having convex structure
40: decorative panel
42: glass panel

What is claimed is:

1. A decorative film comprising:
a reflective layer including a region having a reflectivity of at least 5% or more; and
a layer having a convex structure with a height of at least 1 μm or more on an outermost surface.

2. The decorative film according to claim 1,
wherein a total light transmittance in a wavelength range of 380 nm or more and 800 nm or less is 50% or more.

3. The decorative film according to claim 1,
wherein at least a part of the convex structure has a height of 5 μm or more.

4. The decorative film according to claim 1,
wherein at least a part of the convex structure has light absorbability.

5. The decorative film according to claim 1,
wherein the reflective layer is a layer including a cholesteric liquid crystal.

6. The decorative film according to claim 1, further comprising:
a λ/4 phase difference plate or a circularly polarizing plate at a position opposite to a surface having an uneven structure with a depth of at least 1 μm or more with respect to the reflective layer.

7. The decorative film according to claim 1, further comprising:
a resin base material on a side of the reflective layer opposite to a side on which the layer having a convex structure is provided.

8. The decorative film according to claim 1,
wherein the layer having a convex structure contains coloring particles.

9. The decorative film according to claim 1,
wherein the layer having a convex structure contains black particles.

10. A decorative panel comprising:
the decorative film according to claim 1.

11. A display device comprising:
the decorative panel according to claim 10.

12. The display device according to claim 11,
wherein emitted light of the display device is linearly polarized light.

13. The display device according to claim 11,
wherein the display device is a liquid crystal display device or an organic electroluminescent display device.
